(19) United States
(12) Patent Application Publication
(10) Pub. No.: US 2025/0374747 A1
(43) Pub. Date: Dec. 4, 2025

(54) ELECTROLUMINESCENT DEVICE AND DISPLAY INCLUDING THE SAME

(71) Applicant: SAMSUNG ELECTRONICS CO., LTD., Suwon-si (KR)

(72) Inventors: Kwang Hee KIM, Suwon-si (KR); Hogeun CHANG, Suwon-si (KR); Tae-Gon KIM, Suwon-si (KR); Hyundong Ha, Suwon-si (KR); Ji Hyun MIN, Suwon-si (KR); Daeun YOON, Suwon-si (KR); Jae Yong LEE, Suwon-si (KR)

(21) Appl. No.: 19/227,716

(22) Filed: Jun. 4, 2025

(30) Foreign Application Priority Data
Jun. 4, 2024 (KR) 10-2024-0073301

(51) Int. Cl. H10K 50/115; H10K 50/12; H10K 71/13

(52) U.S. Cl. CPC H10K 50/115; H10K 50/12; H10K 71/13

(57) ABSTRACT

An electroluminescent device, a manufacturing method, and a display device. An electroluminescent device of an embodiment includes a first electrode and a second electrode spaced apart from each other, and a light emitting layer disposed between the first electrode and the second electrode and including a semiconductor nanoparticle, where the semiconductor nanoparticle is configured to emit blue light, an peak emission wavelength of the blue light is greater than or equal to about 440 nanometers and less than or equal to about 480 nanometers, the semiconductor nanoparticle includes zinc, tellurium, selenium, and sulfur, the semiconductor nanoparticle further includes a metal dopant, and the metal dopant includes aluminum, gallium, zirconium, hafnium, magnesium, or a combination thereof.

### CROSS-REFERENCE TO RELATED APPLICATION

This application is based on and claims priority to Korean Patent Application No. 10-2024-0073301 filed in the Korean Intellectual Property Office on Jun. 4, 2024, and all the benefits accruing therefrom under 35 U.S.C. § 119, the content of which in its entirety is incorporated herein by reference.

### BACKGROUND

### 1. Field

The present disclosure relates to an electroluminescent device including a semiconductor nanoparticle, a method for manufacturing the semiconductor nanoparticle, and a display device including the electroluminescent device.

### 2. Description of the Related Art

A semiconductor particle (e.g., a semiconductor nanocrystal particle) having a nanoscale size may exhibit a luminescent property. For example, a quantum dot including the semiconductor nanocrystal may exhibit a quantum confinement effect. Light emission of a semiconductor nanoparticle may be generated while electrons in an excited state transit from a conduction band to a valence band by, for example, light excitation or voltage application. The semiconductor nanoparticle may be controlled to emit light in a desired wavelength region by controlling their sizes and/or compositions. The semiconductor nanoparticles may be used in a light emitting device (e.g., an electroluminescent device) and display devices including the electroluminescent device.

### SUMMARY

Embodiments relate to a light emitting device (e.g., an electroluminescent device) that emits light by itself when voltage is applied to the semiconductor nanoparticle (e.g., a quantum dot).

Embodiments relate to a display device (e.g., a QD-LED display) including a nanocrystal particle (e.g., a quantum dot) as light emitting materials in red/green/blue pixels.

Embodiments relate to a method for producing the semiconductor nanoparticle included in the light emitting device.

Embodiments relate to the semiconductor nanoparticle.

In an embodiment, the electroluminescent device includes a first electrode and a second electrode spaced apart from each other, and a light emitting layer including a semiconductor nanoparticle and disposed between the first electrode and the second electrode,
wherein the semiconductor nanoparticle is configured to emit blue light,
a peak emission wavelength of the blue light is greater than or equal to about 440 nanometers (nm) and less than or equal to about 480 nm,
the semiconductor nanoparticle includes zinc, tellurium, selenium, and sulfur,
the semiconductor nanoparticle further includes a metal dopant, and
the metal dopant includes aluminum, gallium, zirconium, hafnium, magnesium, or a combination thereof.

The semiconductor nanoparticle may not include cadmium.

In the semiconductor nanoparticle, a mole ratio of tellurium to selenium (Te/Se) may be less than about 0.1.

The metal dopant may include aluminum, and in the semiconductor nanoparticle, a mole ratio of aluminum to sulfur (Al/S) may be less than or equal to about 0.09. The metal dopant may include gallium, and in the semiconductor nanoparticle, a mole ratio of gallium to sulfur (Ga/S) may be greater than or equal to about 0.1, or greater than or equal to about 0.14. The metal dopant may include zirconium, and in the semiconductor nanoparticle, a mole ratio of zirconium to sulfur (Zr/S) may be greater than or equal to about 0.05, or greater than or equal to about 0.09.

The metal dopant may include aluminum, and in the semiconductor nanoparticle, a mole ratio of aluminum to zinc may be greater than or equal to about 0.001 and less than or equal to about 0.4, or less than or equal to about 0.1. The metal dopant may include gallium, and in the semiconductor nanoparticle, a mole ratio of gallium to zinc may be greater than or equal to about 0.01, or greater than or equal to about 0.03 and less than or equal to about 0.4, or less than or equal to about 0.1. The metal dopant may include zirconium, and in the semiconductor nanoparticle, a mole ratio of zirconium to zinc may be greater than or equal to about 0.01, or greater than or equal to about 0.03 and less than or equal to about 0.4, or less than or equal to about 0.1.

The peak emission wavelength (e.g., photoluminescent peak wavelength or electroluminescent peak wavelength) of the blue light or the semiconductor nanoparticle may be greater than or equal to about 445 nm and less than or equal to about 475 nm. The peak emission wavelength may be greater than or equal to about 450 nm, greater than or equal to about 455 nm, greater than or equal to about 458 nm, greater than or equal to about 460 nm, greater than or equal to about 463 nm, or greater than or equal to about 465 nm. The peak emission wavelength may be in a range of less than about 480 nm, less than or equal to about 478 nm, or less than or equal to about 475 nm.

The semiconductor nanoparticle may include a first zinc chalcogenide or a first semiconductor nanocrystal including the first zinc chalcogenide; and a third zinc chalcogenide or a third semiconductor nanocrystal including the third zinc chalcogenide, wherein the first zinc chalcogenide or the first semiconductor nanocrystal includes zinc, selenium, and tellurium, and the third zinc chalcogenide or the third semiconductor nanocrystal may include zinc, sulfur, or optionally selenium.

The semiconductor nanoparticle may include a second zinc chalcogenide or a second semiconductor nanocrystal including the second zinc chalcogenide, and the second zinc chalcogenide or the second semiconductor nanocrystal may include zinc, selenium, and optionally sulfur.

The semiconductor nanoparticle may include a core; and a semiconductor nanocrystal shell disposed on the core. The core may include the first zinc chalcogenide (or the first semiconductor nanocrystal). The semiconductor nanocrystal shell may be different from the first semiconductor nanocrystal and may include zinc, selenium, and sulfur.

The semiconductor nanocrystal shell may include a second semiconductor nanocrystal (or a middle shell layer including the same) including a second zinc chalcogenide including zinc and selenium, and a third semiconductor nanocrystal (or an outer layer including the same) including a third zinc chalcogenide including zinc and sulfur. The second zinc chalcogenide may have a different composition from the third zinc chalcogenide. The second zinc chalcogenide may or may not further include sulfur. The third zinc chalcogenide may or may not further include selenium.

The second semiconductor nanocrystal (or the middle shell layer) may be disposed between the first semiconductor nanocrystal (or the core) and the third semiconductor nanocrystal (or the outer layer or outer shell layer).

A size of the first semiconductor nanocrystal or the core may be greater than or equal to about 2 nm, greater than or equal to about 3 nm, or greater than or equal to about 3.5 nm. The size of the first semiconductor nanocrystal or the core may be less than or equal to about 5 nm, less than or equal to about 4.5 nm, less than or equal to about 4 nm, or less than or equal to about 3.8 nm.

A thickness of the second semiconductor nanocrystal (or the middle shell layer) may be greater than or equal to about 1 nm, greater than or equal to about 1.5 nm, greater than or equal to about 2 nm, greater than or equal to about 2.5 nm, greater than or equal to about 2.6 nm, greater than or equal to about 2.8 nm, greater than or equal to about 3 nm, or greater than or equal to about 3.5 nm. The thickness of the second semiconductor nanocrystal (or middle shell layer) may be less than or equal to about 6 nm, less than or equal to about 5.5 nm, less than or equal to about 5 nm, less than or equal to about 4 nm, less than or equal to about 3 nm, or less than or equal to about 2.8 nm.

A thickness of the third semiconductor nanocrystal (or the outer layer) may be less than or equal to about 3 nm, less than or equal to about 2.5 nm, less than or equal to about 2 nm, less than or equal to about 1.5 nm, less than or equal to about 1.2 nm, less than or equal to about 1 nm, or less than or equal to about 0.8 nm. The thickness of the third semiconductor nanocrystal may be greater than or equal to about 0.25 nm, greater than or equal to about 0.5 nm, greater than or equal to about 1 nm, greater than or equal to about 1.3 nm, greater than or equal to about 1.4 nm, greater than or equal to about 1.5 nm, or greater than or equal to about 1.8 nm.

In the semiconductor nanoparticle, the metal dopant may be included in the third semiconductor nanocrystal. The metal dopant may be included within the third semiconductor nanocrystal, for example within the crystal lattice or between adjacent lattices, or may be disposed on the surface of the semiconductor nanoparticle.

The semiconductor nanoparticle may have a particle size (or average particle size, hereinafter referred to as particle size) of greater than or equal to about 9 nm, greater than or equal to about 10 nm, greater than or equal to about 10.5 nm, greater than or equal to about 11 nm, greater than or equal to about 11.5 nm, or greater than or equal to about 12 nm and less than or equal to about 50 nm, less than or equal to about 15 nm, less than or equal to about 13 nm, less than or equal to about 12.5 nm, less than or equal to about 12 nm, or less than or equal to about 11.5 nm.

The semiconductor nanoparticles may have an average particle size of less than or equal to about 45 nm, or less than or equal to about 30 nm.

The semiconductor nanoparticle may be configured to exhibit a quantum yield of greater than or equal to about 80%. The semiconductor nanoparticle may be configured to exhibit a full width at half maximum of less than or equal to about 50 nm. The semiconductor nanoparticle may have an (absolute) quantum yield of greater than or equal to about 82%. The (absolute) quantum yield of the semiconductor nanoparticle may be greater than or equal to about 84%. The (absolute) quantum yield of the semiconductor nanoparticle may be greater than or equal to about 88%. The (absolute) quantum yield of the semiconductor nanoparticle may be greater than or equal to about 90%. The full width at half maximum of the semiconductor nanoparticle may be less than or equal to about 49 nm. The full width at half maximum of the semiconductor nanoparticle may be less than or equal to about 47 nm.

In the semiconductor nanoparticle, a mole ratio (Te/Se) of tellurium to selenium may be less than or equal to about 0.09, less than or equal to about 0.07, less than or equal to about 0.06, less than or equal to about 0.04, less than or equal to about 0.03, or less than or equal to about 0.01. The mole ratio (Te/Se) of tellurium to selenium may be greater than or equal to about 0.00001, greater than or equal to about 0.0001, greater than or equal to about 0.001, or greater than or equal to about 0.005.

In the semiconductor nanoparticle, the mole ratio (Te/Zn) of tellurium to zinc may be less than or equal to about 0.09, less than or equal to about 0.07, less than or equal to about 0.06, less than or equal to about 0.04, less than or equal to about 0.03, or less than or equal to about 0.01. The mole ratio (Te/Zn) of tellurium to zinc may be greater than or equal to about 0.00001, greater than or equal to about 0.0001, greater than or equal to about 0.001, or greater than or equal to about 0.002.

In the semiconductor nanoparticle, the mole ratio (Te/S) of tellurium to sulfur may be greater than or equal to about 0.008, or greater than or equal to about 0.01. In the semiconductor nanoparticle, the mole ratio of tellurium to sulfur may be less than or equal to about 0.05.

In the semiconductor nanoparticle, a mole ratio (Se/(Se+S)) of selenium to the total sum of selenium and sulfur may be greater than or equal to about 0.57, greater than or equal to about 0.58, or greater than or equal to about 0.6 and less than or equal to about 0.99, or less than or equal to about 0.8. In the semiconductor nanoparticle, a mole ratio (S/Se) of sulfur to selenium may be greater than or equal to about 0.1, greater than or equal to about 0.25, greater than or equal to about 0.3, greater than or equal to about 0.35, greater than or equal to about 0.38, greater than or equal to about 0.4, greater than or equal to about 0.42, greater than or equal to about 0.45, or greater than or equal to about 0.5. In the semiconductor nanoparticle, the mole ratio of sulfur to selenium may be less than or equal to about 1.6, less than or equal to about 1.5, less than or equal to about 1.4, less than or equal to about 1.3, less than or equal to about 1.2, less than or equal to about 1.1, less than or equal to about 1.0, or less than or equal to about 0.7.

In the semiconductor nanoparticle, a mole ratio (S/(Se+Te)) of sulfur to the total sum of selenium and tellurium may be greater than or equal to about 0.1, greater than or equal to about 0.3, or greater than or equal to about 0.5. In the semiconductor nanoparticle, the mole ratio (S/(Se+Te)) of sulfur to the total sum of selenium and tellurium may be less than or equal to about 1.5, less than or equal to about 1.3, less than or equal to about 1.2, less than or equal to about 1.1, less than or equal to about 1.0, less than or equal to about 0.9, less than or equal to about 0.8, less than or equal to about 0.7, or less than or equal to about 0.6.

In the semiconductor nanoparticle, a mole ratio (Zn/(Se+S+Te)) of zinc to selenium, sulfur, and tellurium may be greater than or equal to about 0.8, greater than or equal to about 0.9, or greater than or equal to about 1. In the semiconductor nanoparticle, the mole ratio of zinc to selenium, sulfur, and tellurium may be less than or equal to about 2, less than or equal to about 1.5, or less than or equal to about 1.3.

In the semiconductor nanoparticle, a mole ratio (Zn/(Se+S)) of zinc to selenium and sulfur may be greater than or equal to about 0.8, greater than or equal to about 0.9, or greater than or equal to about 1. In the semiconductor nanoparticle, the mole ratio of zinc to selenium and sulfur may be less than or equal to about 2, less than or equal to about 1.5, or less than or equal to about 1.3.

In the semiconductor nanoparticle, a mole ratio of the metal dopant to tellurium may be greater than or equal to about 0.001, greater than or equal to about 0.005, greater than or equal to about 0.01, greater than or equal to about 0.05, or greater than or equal to about 0.1. In the semiconductor nanoparticle, the mole ratio of the metal dopant to tellurium may be less than or equal to about 50, less than or equal to about 40, less than or equal to about 30, less than or equal to about 20, or less than or equal to about 10.

In the semiconductor nanoparticle, the mole ratio of the metal dopant to zinc may be greater than or equal to about 0.001, greater than or equal to about 0.002, greater than or equal to about 0.003, greater than or equal to about 0.004, greater than or equal to about 0.005, greater than or equal to about 0.01, greater than or equal to about 0.02, greater than or equal to about 0.03, greater than or equal to about 0.04, or greater than or equal to about 0.05. In the semiconductor nanoparticle, the mole ratio of the metal dopant to zinc may be less than or equal to about 0.5, less than or equal to about 0.4, less than or equal to about 0.3, less than or equal to about 0.2, less than or equal to about 0.1, less than or equal to about 0.08, less than or equal to about 0.06, or less than or equal to about 0.04.

In the semiconductor nanoparticle, a content of the metal dopant relative to the total cations may be less than or equal to about 20 atom percent (at %), less than or equal to about 10 at %, or less than or equal to about 5 at %. In the semiconductor nanoparticle, the content of the metal dopant relative to the total cations may be greater than or equal to about 0.01 at %, greater than or equal to about 0.05 at %, or greater than or equal to about 0.1 at %.

The semiconductor nanoparticle may or may not further include indium, copper, or a combination thereof. The semiconductor nanoparticle may or may not further include indium phosphide, copper indium sulfide, or a combination thereof. The semiconductor nanoparticle may not include a Group 11-13 compound, a Group Nov. 13, 2016 compound, or a combination thereof.

The light emitting layer may have a ratio of a dopant metal intensity to an S intensity at a center of a (average) thickness of the light emitting layer (for example, 50 seconds when the total thickness is 100 s measured by sputtering time) as confirmed by a depth profile of secondary ion mass spectrometry of greater than or equal to about 0.01, greater than or equal to about 0.05, greater than or equal to about 0.08, greater than or equal to about 0.1, greater than or equal to about 0.15, greater than or equal to about 0.2, greater than or equal to about 0.25, or greater than or equal to about 0.3. The light emitting layer may have a ratio of the dopant metal intensity to the S intensity at the center of the (average) thickness of the light emitting layer (for example, 50 seconds when the total thickness is 100 s measured by sputtering time) as confirmed by the depth profile of secondary ion mass spectrometry of less than or equal to about 10, less than or equal to about 9, less than or equal to about 7, less than or equal to about 6, less than or equal to about 5, less than or equal to about 4, less than or equal to about 3, less than or equal to about 2, less than or equal to about 1, less than or equal to about 0.7, less than or equal to about 0.5, or less than or equal to about 0.4.

The electroluminescent device may have a maximum external quantum efficiency of greater than or equal to about 3%, greater than or equal to about 6%, or greater than or equal to about 10%.

The electroluminescent device may have a maximum luminance of greater than or equal to about 50,000 candelas per square meter (cd/m²) or greater than or equal to about 100,000 cd/m².

The first electrode may be an anode and the second electrode may be a cathode.

The electroluminescent device may further include a charge auxiliary layer between the light emitting layer and the first electrode, between the light emitting layer and the second electrode, or both.

The electroluminescent device may further include a hole auxiliary layer between the light emitting layer and the first electrode.

The electroluminescent device may further include an electron auxiliary layer between the light emitting layer and the second electrode.

The charge auxiliary layer may include a hole auxiliary layer including an organic compound, an electron auxiliary layer including metal oxide nanoparticles, or a combination thereof.

An embodiment relates to the semiconductor nanoparticle included in the electroluminescent device.

Details of the semiconductor nanoparticle are as described herein.

When the semiconductor nanoparticle are included in an electron-only device having a structure of an electrode/an electron transport layer including ZnMgO metal oxide/a light emitting layer including the semiconductor nanoparticle/electron transport layer including ZnMgO metal oxide/an electrode, the semiconductor nanoparticle may be configured to exhibit an electron transport ability that is at least twice (for example, at least three times, or at least four times) higher in current density at 5 volts in the third sweep, compared to a semiconductor nanoparticle that does not include the metal dopant.

An embodiment relates to a method for producing the semiconductor nanoparticle, the method including: admixing a particle including zinc, selenium, and tellurium, a zinc precursor, and a sulfur precursor into a reaction medium; and heating the reaction medium to a reaction temperature,
wherein in the method, the sulfur precursor includes a product from a reaction between a metal dopant compound and an organic thiol compound, the metal dopant compound includes aluminum, magnesium, gallium, zirconium, hafnium, or a combination thereof, the reaction of the metal dopant compound and the organic thiol compound is performed at a first temperature of less than about 100° C., and the reaction temperature is greater than or equal to about 245° C. and less than or equal to about 400° C. The reaction of the metal dopant compound and the organic thiol compound may include contacting the metal dopant compound and the organic thiol compound at a temperature of less than or equal to about 50° C., and may not involve separate heating. By the admixing and heating, the zinc precursor and the sulfur precursor may react in the presence of the particle to form a semiconductor nanocrystal layer (or outermost layer). The reaction medium may include an organic solvent and optionally an organic ligand. The reaction medium may be vacuum treated at a predetermined temperature (e.g., a temperature of greater than or equal to about 100° C. and less than or equal to about 200° C.).

The semiconductor nanoparticle may include a first zinc chalcogenide (or a first semiconductor nanocrystal including the same) including zinc, selenium, and tellurium.

The semiconductor nanoparticle may include a second zinc chalcogenide (or a second semiconductor nanocrystal including the same) including zinc, selenium, and optionally sulfur. The second semiconductor nanocrystal may be disposed on the first semiconductor nanocrystal.

A semiconductor nanocrystal layer (or outermost layer) may be formed on the semiconductor nanoparticle by the admixing and heating.

The sulfur precursor may not include sulfur-TOP.

The metal dopant compound may undergo an exothermic reaction with the organic thiol compound at a temperature of greater than or equal to about 30° C. and less than or equal to about 50° C.

The metal dopant compound may include a C1-C30 or C2-C8 or C3-C5 hydrocarbon group, a C1-C30 or C2-C8 or C3-C5 amino group (e.g., an alkyl amino group), or a combination thereof, bonded to a central metal, and the central metal may include aluminum, magnesium, gallium, zirconium, hafnium, or a combination thereof.

The organic thiol compound may include a monothiol compound, a polythiol compound, or a combination thereof.

The organic thiol compound may include a hydrocarbon group of C3-C30, C5-C20, C8-C18, or C10-C12.

In the metal dopant compound or the organic thiol, the hydrocarbon group may include a (linear or branched) aliphatic hydrocarbon group, an aromatic hydrocarbon group, or a combination thereof. The hydrocarbon group may or may not further include oxygen, nitrogen, or a combination thereof.

The aliphatic hydrocarbon group may include an alkyl group, an alkenyl group, or an alkynyl group. The (aliphatic) hydrocarbon group may include methyl, ethyl, propyl, butyl, pentyl, hexyl, or a combination thereof.

The admixing may be performed one or more times, or two or more times.

In the method, the reaction temperature may be greater than or equal to about 280° C., greater than or equal to about 300° C., or greater than or equal to about 325° C. The reaction temperature may be less than or equal to about 380° C., less than or equal to about 360° C., or less than or equal to about 350° C.

An embodiment relates to a method for manufacturing the electroluminescent device described above, including: disposing the light emitting layer comprising the semiconductor nanoparticle on the first electrode; and disposing the second electrode on the light emitting layer.

An embodiment relates to an electronic device or a display device/apparatus including the electroluminescent device or the semiconductor nanoparticle.

The display device or electronic device may include a virtual reality display device, an augmented reality display device, a portable terminal device, a monitor, a laptop, a television, an electronic board, a camera, or an electrical component.

An electroluminescent device of an embodiment includes semiconductor nanoparticle including a metal dopant (e.g., in a shell layer or outermost layer including zinc sulfide) within a light emitting layer (e.g., capable of providing a wide bandgap in the form of an oxide). The semiconductor nanoparticle can contribute to enabling the electroluminescent device to stably and efficiently provide a desired level of an electroluminescent property for an extended period of time. In an embodiment, the semiconductor nanoparticle may exhibit increased stability (e.g., enhanced light stability when exposed to ultraviolet visual (UV) light).

The semiconductor nanoparticle produced according to the method of an embodiment can exhibit higher electron transport characteristics compared to undoped semiconductor nanoparticle having the same composition/structure, and thus, when included in a light emitting layer in an electroluminescent device, can enable rapid electron injection and realize low-voltage operation of the device.

### BRIEF DESCRIPTION OF THE DRAWINGS

FIG. 1 is a schematic cross-sectional view of a QD LED device according to a non-limiting embodiment.

FIG. 2 is a schematic cross-sectional view of a QD LED device according to another non-limiting embodiment.

FIG. 3 is a schematic cross-sectional view of a QD LED device according to another non-limiting embodiment.

FIG. 4 is a schematic cross-sectional view of a QD LED device according to another non-limiting embodiment.

FIG. 5 is a schematic cross-sectional view of a light emitting device (RGB pixel) according to an embodiment.

FIG. 6 is a schematic front view of a display panel according to an embodiment.

FIG. 7 is a schematic cross-sectional view of the display panel of FIG. 6 taken along line IV-IV.

FIG. 8 illustrates a graph showing intensity versus sputtering time of the results (SIMS depth profile) of Experimental Example 1 (i.e., secondary ion mass spectrometry analysis experiment of the light emitting layer of the electroluminescent device manufactured in Example 1).

FIG. 9 is a diagram showing relative photoluminescence intensity (percent, %) versus time (minutes, min) the results of Experimental Example 2.

### DETAILED DESCRIPTION

Hereinafter, with reference to the accompanying drawings, various embodiments of the present disclosure will be described in detail so that those of ordinary skill in the art can easily carry out the present disclosure. The present disclosure may be embodied in many different forms and is not limited to the embodiments described herein.

In order to clearly explain the present disclosure, parts irrelevant to the description are omitted, and the same reference numerals are assigned to the same or similar elements throughout the specification.

The size and thickness of each constituent element as shown in the drawings are randomly indicated for better understanding and ease of description, and this disclosure is not necessarily limited to as shown. In the drawings, the thickness of layers, films, panels, regions, or the like, are exaggerated for clarity. And in the drawings, for convenience of description, the thickness of some layers and regions are exaggerated.

In addition, it will be understood that when an element such as a layer, film, region, or substrate is referred to as being “on” another element, it can be directly on the other element or intervening elements may also be present. In contrast, when an element is referred to as being “directly on” another element, there are no intervening elements present. Also, to be disposed “on” the reference portion means to be disposed above or below the reference portion, and does not necessarily mean “above” in an opposite direction of gravity.

In addition, unless explicitly described to the contrary, the word “comprise” and variations such as “comprises” or “comprising” will be understood to imply the inclusion of stated elements but not the exclusion of any other elements.

In the specification, “cross-section” may mean a cross-section viewed from the side that is cut generally vertically (e.g., substantially vertically to the bottom surface) through the target portion.

Further, the singular includes the plural unless mentioned otherwise.

In the drawings, the thickness of layers, films, panels, regions, or the like, are exaggerated for clarity. Like reference numerals designate like elements throughout the specification.

Hereinafter, values of a work function or (HOMO or LUMO) energy levels are expressed as an absolute value from a vacuum level. In addition, a deep, a high, or large work function or energy level means that the absolute value is large when the vacuum level is set to “0 electron volts (eV),” and a shallow, low, or small work function or energy level means that the absolute value is small when the vacuum level is set to “0 eV.”

In an embodiment, the work function may refer to a minimum energy required to remove an electron from a solid metal (e.g., the metal surface) to a vacuum (e.g., the portion just outside the solid surface).

As used herein, the average may be mean or median. In an embodiment, the average is the mean.

As used herein, the peak emission wavelength refers to the wavelength at which the emission spectrum of a given light reaches its maximum.

As used herein, when a definition is not otherwise provided, “Group” in the term Group III, Group II, and the like refers to a group of Periodic Table.

As used herein, “Group II” refers to Group IIA and Group IIB, and examples of Group II metal may be Cd, Zn, Hg, and Mg, but are not limited thereto.

“Group III” may include Group IIIA and Group IIIB, examples of Group III metals include, but are not limited to, Al, In, Ga, and Tl.

As used herein, “Group IV” refers to Group IVA and Group IVB, and examples of a Group IV metal may be Si, Ge, and Sn, but are not limited thereto. As used herein, “metal” may include a semi-metal such as Si.

As used herein, “Group I” refers to Group IA and Group IB, and examples may include Li, Na, K, Rb, and Cs, but are not limited thereto.

“Group V” includes Group VA and includes, but is not limited to, nitrogen, phosphorus, arsenic, antimony, and bismuth.

As used herein, “Group VI” refers to Group VIA, and examples may include sulfur, selenium, tellurium, but are not limited thereto.

The metal includes a semi-metal such as Si.

As used herein, when a definition is not otherwise provided, “substituted” refers to replacement of at least one hydrogen of a compound or the corresponding moiety by a substituent selected from a C1 to C30 alkyl group, a C2 to C30 alkenyl group, a C2 to C30 alkynyl group, a C6 to C30 aryl group, a C7 to C30 alkylaryl group, a C1 to C30 alkoxy group, a C1 to C30 heteroalkyl group, a C3 to C30 heteroaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino group (—NRR′ wherein R and R′ are independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), and a combination thereof.

As used herein, the hydrocarbon group refers to a group including carbon and hydrogen (e.g., an aliphatic group such as alkyl, alkenyl, or alkynyl group, or an aromatic group such as aryl group).

The hydrocarbon group may be a group having a monovalence or more formed by removal of one or more hydrogen atoms from alkane, alkene, alkyne, or arene. In the hydrocarbon group, at least one methylene may be replaced by an oxide moiety, a carbonyl moiety, an ester moiety, —NH—, or a combination thereof. Unless otherwise stated to the contrary, the hydrocarbon (alkyl, alkenyl, alkynyl, or aryl) group may have 1 to 60, 2 to 32, 3 to 24, or 4 to 12 carbon atoms.

As used herein, “alkyl” refers to a linear or branched saturated monovalent hydrocarbon group (methyl, ethyl hexyl, or the like).

As used herein, “alkenyl” refers to a linear or branched monovalent hydrocarbon group having one or more carbon-carbon double bond.

As used herein, “alkynyl” refers to a linear or branched monovalent hydrocarbon group having one or more carbon-carbon triple bond.

As used herein, “aryl” refers to a group formed by removal of at least one hydrogen from an aromatic group (e.g., a phenyl or naphthyl group).

As used herein, “hetero” refers to one including 1 to 3 heteroatoms of N, O, S, Si, P, or a combination thereof.

As used herein, “alkoxy” means alkyl group linked via an oxygen (i.e., alkyl-O—), such as a methoxy, ethoxy, or sec-butyloxy group.

An “amine group” may be —NRR, wherein (Rs are independently hydrogen, a C1 to C12 alkyl group, a C7 to C20 alkylarylene group, a C7 to C20 arylalkylene group, or a C6 to C18 aryl group.

As used herein, the expression “not including cadmium (or other harmful heavy metal)” may refer to the case in which a concentration of cadmium (or another heavy metal deemed harmful) may be less than or equal to about 100 parts per million by weight (ppmw), less than or equal to about 50 ppmw, less than or equal to about 10 ppmw, less than or equal to about 1 ppmw, less than or equal to about 0.1 ppmw, less than or equal to about 0.01 ppmw, or about zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

“About” “substantially” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system)

For example, “substantially” or “approximately” can mean within +10%, 5%, 3%, or 1% or within standard deviation of the stated value.

As used herein, a nanoparticle is a structure having a, e.g., at least one, region or characteristic dimension with a nanoscale dimension. In an embodiment, a dimension (or an average dimension) of the nanostructure is less than or equal to about 500 nm, less than or equal to about 300 nm, less than or equal to about 250 nm, less than or equal to about 150 nm, less than or equal to about 100 nm, less than or equal to about 50 nm, or less than or equal to about 30 nm. Such a nanoparticle may have any shape.

The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape having such as at least two pods, or the like and is not limited thereto. The nanoparticle can be, e.g., substantially crystalline, substantially monocrystalline, polycrystalline, (for example, at least partially) amorphous, or a combination thereof.

For example, a semiconductor nanoparticle such as a quantum dot may exhibit quantum confinement or exciton confinement. In the present specification, the term “nanoparticle or quantum dot” is not limited in its shape unless specifically defined. A semiconductor nanoparticle, such as a quantum dot, may have a size smaller than a diameter of Bohr excitation in the bulk crystal of the same material, and may exhibit a quantum confinement effect. The quantum dot may emit light corresponding to their bandgap energy by controlling the size of the emission center of the nanocrystal.

As used herein, the term “T50” is a time (hours, hr) the brightness (e.g., luminance) of a given device decreases to 50% of the initial brightness (100%) as, e.g., when, the given device is started to be driven, e.g., operated, at a predetermined initial brightness (e.g., 650 nit or 146 nit).

As used herein, the term “T90” is a time (hr) the brightness (e.g., luminance) of a given device decreases to 90% of the initial brightness (100%) as the given device is started to be driven at a predetermined initial brightness (e.g., 650 nit or 146 nit).

As used herein, external quantum efficiency (EQE) refers to a ratio of the number of photons emitted from a light emitting diode (LED) to the number of electrons passing through the device. EQE may be criteria of how efficiently the light emitting diode converts the electrons into the photons and allows them to escape. In an embodiment, EQE may be determined based on the following equation:

$$EQE = [ Injection efficiency ] \times [ Solid state quantum yield ] \times [ Extraction efficiency ]$$

$$Injection efficiency = proportion of electrons passing through the device that are injected into the active region ;$$

$$Solid state quantum yield = proportion of all electron - hole recombinations in the active region that are radiative and thus , produce photons ; and ;$$

$$Extraction efficiency = proportion of photons generated in the active region that escape from the device .$$

As used herein, the maximum external quantum efficiency refers to the maximum value of the external quantum efficiency.

As used herein, the maximum luminance refers to a maximum value of luminance that the device can achieve.

As used herein, quantum efficiency is a term used interchangeably with quantum yield. Quantum efficiency (or quantum yield) may be measured either in solution or in the solid state (in a composite). In an embodiment, quantum efficiency (or quantum yield) is the ratio of photons emitted to photons absorbed by the nanostructure or population thereof. In an embodiment, quantum efficiency may be measured by any method. For example, for fluorescence quantum yield or efficiency, there may be two methods: an absolute method and a relative method.

In the absolute method, quantum efficiency is obtained by detecting the fluorescence of all samples through an integrating sphere. In the relative method, the quantum efficiency of the unknown sample is calculated by comparing the fluorescence intensity of a standard dye (standard sample) with the fluorescence intensity of the unknown sample. Coumarin 153, Coumarin 545, Rhodamine 101 inner salt, Anthracene and Rhodamine 6G may be used as standard dyes according to their photoluminescence (PL) wavelengths, but the present disclosure is not limited thereto.

Unless otherwise stated, numerical ranges stated herein are inclusive.

In an embodiment, the “dispersion” may be one in which the dispersed phase is a solid and the continuous medium includes a liquid. In an embodiment, “dispersion” may refer to a colloidal dispersion wherein the dispersed phase has a dimension of greater than or equal to about 1 nm, for example, greater than or equal to about 2 nm, greater than or equal to about 3 nm, greater than or equal to about 4 nm, greater than or equal to about 5 nm, or greater than or equal to about 10 nm and several micrometers (μm) or less, (e.g., less than or equal to about 2 μm, or less than or equal to about 1 μm, less than or equal to about 900 nm, less than or equal to about 800 nm, less than or equal to about 700 nm, less than or equal to about 600 nm, or less than or equal to about 500 nm).

A bandgap energy of the semiconductor nanoparticle may be changed according to a size, a structure, and a composition of nanocrystal. For example, as the size of the quantum dot increases, the quantum dot may have a narrow bandgap energy and an increased emission wavelength. The semiconductor nanocrystal has drawn attention as light emitting materials in various fields of a display device, an energy device, or a bio light emitting device.

Semiconductor nanoparticles having an electroluminescent property at a practically applicable level may include harmful heavy metals such as cadmium (Cd), lead, mercury, or a combination thereof. It is desirable to provide a semiconductor nanoparticle that emits light of a desired wavelength while being substantially free of the harmful heavy metals. In addition, from an environmental point of view, it is desirable to provide a light emitting device or a display device having a light emitting layer based on the semiconductor nanoparticle that does not include cadmium, a harmful heavy metal.

A semiconductor nanoparticle according to an embodiment is environmentally friendly, can emit blue light of a desired wavelength with improved luminous efficiency, and can exhibit improved stability in the external environment. An electroluminescent device according to an embodiment is a self-emissive light emitting device that includes the semiconductor nanoparticle and is configured to emit desired light by voltage application with or without a separate light source. The light emitting device and display device of an embodiment are desirable from an environmental point of view.

In an embodiment, the semiconductor nanoparticle is configured to emit blue light, wherein an peak emission wavelength of the blue light is greater than or equal to about 440 nm and less than or equal to about 480 nm, the semiconductor nanoparticle includes zinc, tellurium, selenium, and sulfur, the semiconductor nanoparticle further includes a metal dopant, the metal dopant includes aluminum, gallium, zirconium, hafnium, magnesium, or a combination thereof. The semiconductor nanoparticle may not include cadmium. The semiconductor nanoparticle may not include lead, mercury, or a combination thereof. In the semiconductor nanoparticle, a mole ratio of tellurium to selenium may be less than about 0.1.

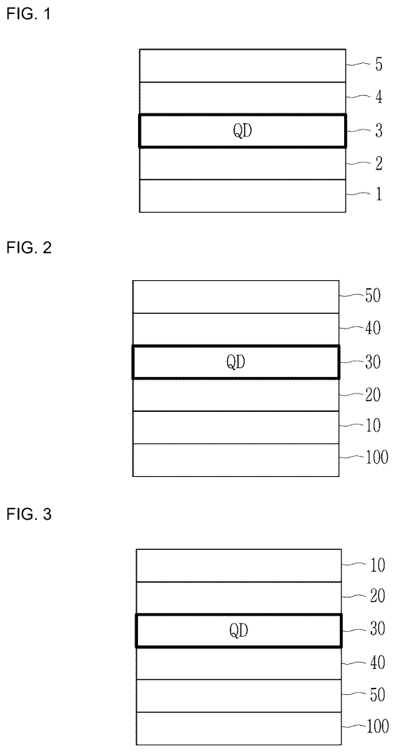

The electroluminescent device of an embodiment includes a first electrode 1 and a second electrode 5 which are spaced apart (e.g., facing each other); and a light emitting layer 3 disposed between the first electrode and the second electrode and including the semiconductor nanoparticle and not including cadmium (see FIG. 1). The first electrode may include an anode, and the second electrode may include a cathode. Alternatively, the first electrode may include a cathode and the second electrode may include an anode. The electroluminescent device may further include a hole auxiliary layer 2 between the light emitting layer 3 and the first electrode 1. The electroluminescent device may further include an electron auxiliary layer 4 between the light emitting layer 3 and the second electrode 5.

In the electroluminescent device, the first electrode 10 or the second electrode 20 may be disposed on a (transparent) substrate 100. The transparent substrate may be a light extraction surface. (Refer to: FIG. 2 and FIG. 3)

Referring to FIGS. 2 and 3, the light emitting layer 30 may be disposed between the first electrode (e.g., anode) 10 and second electrode (e.g., cathode) 50. The second electrode or cathode 50 may include an electron injection conductor. The first electrode or anode 10 may include a hole injection conductor. The work functions of the electron/hole injection conductors included in the second electrode and the first electrode may be appropriately adjusted and are not particularly limited. For example, the second electrode may have a small work function and the first electrode may have a relatively large work function, or vice versa.

The electron/hole injection conductors may include a metal-containing material (e.g., a metal, a metal compound, an alloy, or a combination thereof) (aluminum, magnesium, tungsten, nickel, cobalt, platinum, palladium, calcium, LiF, or the like), a metal oxide such as gallium indium oxide or indium tin oxide (ITO), or a conductive polymer (e.g., having a relatively high work function) such as polyethylene dioxythiophene, but are not limited thereto.

At least one of the first electrode and the second electrode may be a light transmitting electrode or a transparent electrode. In an embodiment, both the first electrode and the second electrode may be a light transmitting electrode. The electrode(s) may be patterned. The first electrode and/or the second electrode may be disposed on a (e.g., insulating) substrate 100. The substrate 100 may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and for example, less than or equal to about 99%, or less than or equal to about 95%). The substrate may further include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light transmitting electrode may be disposed on a (e.g., insulating) transparent substrate. The substrate may be rigid or flexible. The substrate may be plastic, glass, or a metal.

The light transmitting electrode can have a light transmittance of greater than or equal to about 50%, greater than or equal to about 60%, greater than or equal to about 70%, greater than or equal to about 80%, or greater than or equal to about 90%, for example, in the range of about 80% to about 100%, about 85% to about 95%, or a combination thereof.

The light transmitting electrode may include, for example, a transparent conductor such as indium tin oxide (ITO) or indium zinc oxide (IZO), gallium indium tin oxide, zinc indium tin oxide, titanium nitride, polyaniline, LiF/Mg:Ag, or the like, or a thin metal thin film of a single layer or a plurality of layers, but is not limited thereto. The first electrode, the second electrode, or a combination thereof may include silver, aluminum (Al), a lithium aluminum (Li:Al) alloy, a magnesium-silver alloy (Mg:Ag), lithium fluoride-aluminum (LiF:Al), or the like. In an alloy electrode, a ratio between each material can be appropriately controlled, for example, in the range of about 1:0.1 to about 1:10, about 1:0.2 to about 1:5, about 1:0.3 to about 1:3, or a combination thereof.

In an embodiment, the first electrode or the second electrode may be a multilayer electrode. In an embodiment, the first electrode (or anode) may be a multilayer electrode including two or more layers, three or more layers and ten or fewer layers, or five or fewer layers of electrode material. In an embodiment, the second electrode (or cathode) may be a multilayer electrode including two or more layers, three or more layers and ten or fewer layers, or five or fewer layers of electrode material.

The multilayer electrode may include, for example, a light transmitting conductive material (or a transparent conductive material) such as indium tin oxide, an opaque conductive material (or reflective electrode material) such as aluminum, or a combination thereof. In an embodiment, the electrode (e.g., an anode or a cathode) may have a structure in which an opaque conductive material (or a reflective electrode material layer) is disposed between transparent conductive materials (e.g., layers of transparent conductive materials). In an embodiment, the electrode (anode or cathode) may have a structure in which a light transmitting conductive material (e.g., a light transmitting conductive material layer) is disposed between opaque conductive materials (or reflective electrode materials).

When a voltage is applied between the first electrode and the second electrode, the light emitting layer can emit light up and down by the electric field, and the light traveling to the reflective electrode can be reflected and emitted in the opposite direction.

In an embodiment, light may be emitted toward the cathode. In an embodiment, light may be emitted toward the anode.

A thickness of the electrode (the first electrode and/or the second electrode) is not particularly limited and may be appropriately selected in consideration of device efficiency. For example, the thickness of the electrode may be greater than or equal to about 5 nm, for example, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), for example, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, less than or equal to about 100 nm, less than or equal to about 90 nm, less than or equal to about 80 nm, less than or equal to about 70 nm, or less than or equal to about 60 nm.

The method of forming the electrode is not particularly limited and may be appropriately selected depending on the material. In an embodiment, the electrode may be formed by, but is not limited to, deposition, coating, or a combination thereof.

A light emitting layer 3 or 30 is disposed between the first electrode 1 and the second electrode 5 (e.g., the anode 10 and the cathode 50). The light emitting layer includes semiconductor nanoparticle(s) (e.g., blue light emitting nanoparticle, red light emitting nanoparticle, or green light emitting nanoparticle). The light emitting layer may include one or more (e.g., 2 or more or 3 or more and 10 or less) monolayers of a plurality of semiconductor nanoparticles.

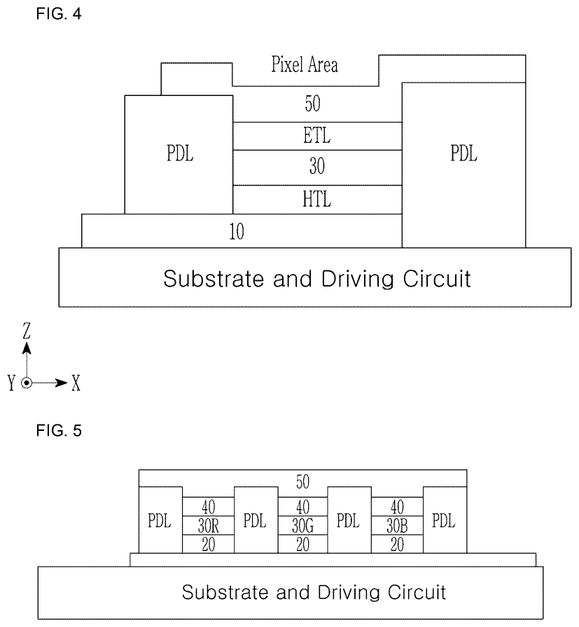

The light emitting layer may be patterned. In an embodiment, the patterned light emitting layer may include a blue light emitting layer (or a blue emitting layer) (e.g., disposed within a blue pixel in a display device to be described later), a red light emitting layer (or a red emitting layer) (e.g., disposed within a red pixel in a display device to be described later), and a green light emitting layer (or a green emitting layer) (e.g., disposed within a green pixel in a display device to be described later)), or a combination thereof. Each of the light emitting layers may be (e.g., optically) separated from an adjacent light emitting layer by a partition wall. In an embodiment, a partition wall or bank such as a black matrix or a pixel defining layer (PDL) may be disposed between the red emitting layer(s), the green emitting layer(s), and the blue emitting layer(s) (refer to FIGS. 4 and 7). In a non-limiting embodiment, the red emitting layer, the green emitting layer, and the blue emitting layer may each be optically substantially isolated.

The light emitting layer or the semiconductor nanoparticle may not include cadmium. The light emitting layer or the semiconductor nanoparticle may not include mercury, lead, or a combination thereof. The semiconductor nanoparticle may not include or may further include copper, manganese, or a combination thereof.

The semiconductor nanoparticle includes zinc, selenium, and sulfur. The semiconductor nanoparticle may have a core-shell structure. The semiconductor nanoparticle or the core-shell structure may include a first semiconductor nanocrystal; and a semiconductor nanocrystal shell (including a third semiconductor nanocrystal) disposed on the first semiconductor nanocrystal; and including zinc and sulfur.

The environmentally-friendly Cd-free blue light-emitting semiconductor nanoparticle (or quantum dot) may have a structure of a ZnSe-containing core and a ZnS shell layer disposed on the core (e.g., a core/shell/shell structure of ZnSe:Te/ZnSe/ZnS). In such a core-shell structured quantum dot, a luminescent center may be a ZnSe-containing core, and a ZnS shell layer having a wider bandgap than that of the core may be disposed on the core. However, the present inventors have found that a semiconductor nanoparticle that exhibits an enhanced quantum yield, for example, in solution after synthesis, may suffer substantial degradation of a luminescent property in an electroluminescent device (for example, over time under the operating environment of the device), and an electroluminescent device including the same may have difficulty exhibiting a desired level of life-span. Without wishing to be bound by any theory, it is believed that the ZnS shell in a blue-emitting semiconductor nanoparticle may be oxidized by the atmosphere in the device operating environment, or that charge injection for device operation causes an electrochemical reaction in the semiconductor nanoparticle, resulting in the oxidation of sulfur on the semiconductor nanoparticle surface (e.g., generation of ZnSOₓ), which in turn acts as a trap on the semiconductor nanoparticle surface to increase the non-luminescent recombination of electrons and holes and reduce the life-span of the EL device.

The semiconductor nanoparticle of an embodiment can emit desired blue light without containing cadmium and exhibit improved stability (e.g., resistance to oxidation in the external atmosphere and operating stability) within an electroluminescent device, and thus, an electroluminescent device including the same in an emitting layer may stably exhibit a desired level of an electroluminescent property for an extended period of time and exhibit an improved life-span characteristic.

The semiconductor nanoparticle includes zinc, selenium, tellurium, and sulfur. The semiconductor nanoparticle further includes a metal dopant. The metal dopant may include a metal that can have a relatively wide bandgap energy (e.g., a bandgap energy of greater than or equal to about 5 eV) when forming an oxide. The bandgap energy may be greater than or equal to about 6 eV, greater than or equal to about 7 eV, or greater than or equal to about 8 eV.

The metal dopant includes aluminum, gallium, zirconium, hafnium, magnesium, or a combination thereof. It is believed that the metal dopant may have a bandgap energy as shown in Table 1 when forming an oxide:

TABLE 1

| | Bandgap energy | LUMO | HOMO |
|---|---|---|---|
| | of oxide | of oxide | of oxide |
| Metal | (eV) | (eV) | (eV) |
| aluminum | 8.8 | −1.0 | −9.8 |
| magnesium | 7.5 | −1.7 | −9.4 |
| gallium | 5.0 | −3.7 | −8.7 |
| zirconium | 5.8 | −2.5 | −8.3 |
| hafnium | 6.0 | −2.4 | −8.4 |

The semiconductor nanoparticle may include a first zinc chalcogenide (or a first semiconductor nanocrystal including the same); and a third zinc chalcogenide (or a third semiconductor nanocrystal including the same), wherein the first zinc chalcogenide may include zinc, selenium, and tellurium, and the third zinc chalcogenide may include zinc, sulfur, or optionally selenium. The semiconductor nanoparticle may include a second zinc chalcogenide (or a second semiconductor nanocrystal including the same) including zinc, selenium, and optionally sulfur. The second zinc chalcogenide (or the second semiconductor nanocrystal including the same) may be disposed between the third zinc chalcogenide (or the third semiconductor nanocrystal including the same) and the first semiconductor nanocrystal. The metal dopant may be disposed within the third zinc chalcogenide or on the surface of the semiconductor nanoparticle. Without wishing to be bound by any theory, it is believed that at least a portion of the metal dopant in the semiconductor nanoparticle of an embodiment may be disposed within the crystal lattice of the second zinc chalcogenide or zinc sulfide or may be disposed interstitially between the lattices of the second zinc chalcogenide or zinc sulfide. In the semiconductor nanoparticle, the metal dopant may be bound to a surface of the semiconductor nanoparticle. According to an embodiment, the semiconductor nanoparticle further including the metal dopant may contribute to improving the operating stability of the device when included in the light emitting layer of the electroluminescent device.

In the semiconductor nanoparticle, a mole ratio (Te/Se) of tellurium to selenium may be less than or equal to about 0.09, less than or equal to about 0.08, less than or equal to about 0.07, less than or equal to about 0.06, less than or equal to about 0.05, less than or equal to about 0.04, less than or equal to about 0.03, less than or equal to about 0.02, less than or equal to about 0.01, less than or equal to about 0.009, less than or equal to about 0.008, less than or equal to about 0.007, less than or equal to about 0.006, less than or equal to about 0.005, less than or equal to about 0.004, less than or equal to about 0.003, or less than or equal to about 0.002. The mole ratio (Te/Se) of tellurium to selenium may be greater than or equal to about 0.0001, greater than or equal to about 0.00015, greater than or equal to about 0.0002, greater than or equal to about 0.00025, greater than or equal to about 0.0003, greater than or equal to about 0.00035, greater than or equal to about 0.0004, greater than or equal to about 0.00045, greater than or equal to about 0.0005, greater than or equal to about 0.00055, greater than or equal to about 0.0006, greater than or equal to about 0.00065, greater than or equal to about 0.0007, greater than or equal to about 0.00075, greater than or equal to about 0.0008, greater than or equal to about 0.00085, greater than or equal to about 0.0009, greater than or equal to about 0.00095, greater than or equal to about 0.001, greater than or equal to about 0.0015, greater than or equal to about 0.002, greater than or equal to about 0.0025, greater than or equal to about 0.003, greater than or equal to about 0.0035, greater than or equal to about 0.004, greater than or equal to about 0.0045, greater than or equal to about 0.005, greater than or equal to about 0.0055, greater than or equal to about 0.006, greater than or equal to about 0.0065, or greater than or equal to about 0.007. In the semiconductor nanoparticle according to an embodiment, the mole ratio (Te/Se) of tellurium to selenium may be about 0.001 to about 0.009, about 0.002 to about 0.008, about 0.003 to about 0.007, about 0.004 to about 0.006, about 0.0045 to about 0.0055, or a combination thereof.

In the semiconductor nanoparticle, a mole ratio (Te/Zn) of tellurium to zinc may be less than or equal to about 0.09, less than or equal to about 0.08, less than or equal to about 0.07, less than or equal to about 0.06, less than or equal to about 0.05, less than or equal to about 0.04, less than or equal to about 0.03, less than or equal to about 0.02, less than or equal to about 0.01, less than or equal to about 0.009, less than or equal to about 0.0085, less than or equal to about 0.008, less than or equal to about 0.0075, less than or equal to about 0.007, less than or equal to about 0.0065, less than or equal to about 0.006, less than or equal to about 0.0055, less than or equal to about 0.005, less than or equal to about 0.0045, or less than or equal to about 0.004. The mole ratio (Te/Zn) of tellurium to zinc may be greater than or equal to about 0.0001, greater than or equal to about 0.0003, greater than or equal to about 0.0005, greater than or equal to about 0.0007, greater than or equal to about 0.0009, greater than or equal to about 0.001, greater than or equal to about 0.0012, greater than or equal to about 0.0014, greater than or equal to about 0.0016, greater than or equal to about 0.0018, greater than or equal to about 0.0019, greater than or equal to about 0.002, greater than or equal to about 0.0021, greater than or equal to about 0.0022, greater than or equal to about 0.0023, greater than or equal to about 0.0024, greater than or equal to about 0.0025, greater than or equal to about 0.0026, greater than or equal to about 0.0027, greater than or equal to about 0.0028, greater than or equal to about 0.0029, greater than or equal to about 0.003, greater than or equal to about 0.0031, greater than or equal to about 0.0032, greater than or equal to about 0.0033, greater than or equal to about 0.0034, greater than or equal to about 0.0035, greater than or equal to about 0.0036, greater than or equal to about 0.0037, greater than or equal to about 0.0038, greater than or equal to about 0.0039, or greater than or equal to about 0.004.

In the semiconductor nanoparticle, a mole ratio (Te/S) of tellurium to sulfur may be greater than or equal to about 0.001, greater than or equal to about 0.003, greater than or equal to about 0.005, greater than or equal to about 0.008, or greater than or equal to about 0.01. In the semiconductor nanoparticle, the mole ratio of tellurium to sulfur may be less than or equal to about 0.05, less than or equal to about 0.03, or less than or equal to about 0.02.

In the semiconductor nanoparticle, a mole ratio (Se/Zn) of Se to Zn may be less than about 1, for example, less than or equal to about 0.7, less than or equal to about 0.6, less than or equal to about 0.55, less than or equal to about 0.5, less than or equal to about 0.45, or less than or equal to about 0.4. The mole ratio (Se/Zn) of Se to Zn may be greater than or equal to about 0.1, for example, greater than or equal to about 0.2, greater than or equal to about 0.3, greater than or equal to about 0.4, greater than or equal to about 0.45, greater than or equal to about 0.46, greater than or equal to about 0.48, greater than or equal to about 0.5, greater than or equal to about 0.51, greater than or equal to about 0.52, greater than or equal to about 0.53, greater than or equal to about 0.54, greater than or equal to about 0.55, greater than or equal to about 0.56, greater than or equal to about 0.57, greater than or equal to about 0.58, greater than or equal to about 0.59, or greater than or equal to about 0.6.

In the semiconductor nanoparticle, a mole ratio (Se/(Se+S)) of selenium to the total sum of selenium and sulfur may be greater than or equal to about 0.5, greater than or equal to about 0.53, greater than or equal to about 0.55, greater than or equal to about 0.57, greater than or equal to about 0.58, greater than or equal to about 0.6, or greater than or equal to about 0.63. In the semiconductor nanoparticle, the mole ratio (Se/(Se+S)) of selenium to the total sum of selenium and sulfur may be less than or equal to about 0.99, less than or equal to about 0.9, less than or equal to about 0.8, less than or equal to about 0.7, or less than or equal to about 0.65.

In the semiconductor nanoparticle, a mole ratio (S/Se) of sulfur to selenium may be greater than or equal to about 0.1, greater than or equal to about 0.2, greater than or equal to about 0.3, greater than or equal to about 0.35, greater than or equal to about 0.4, greater than or equal to about 0.45, greater than or equal to about 0.5, greater than or equal to about 0.55, greater than or equal to about 0.59, greater than or equal to about 0.6, or greater than or equal to about 0.61. In the semiconductor nanoparticle, the mole ratio (S/Se) of sulfur to selenium may be less than or equal to about 2, less than or equal to about 1.8, less than or equal to about 1.6, less than or equal to about 1.5, less than or equal to about 1.4, less than or equal to about 1.35, less than or equal to about 1.3, less than or equal to about 1.25, less than or equal to about 1.2, less than or equal to about 1, less than or equal to about 0.9, less than or equal to about 0.8, less than or equal to about 0.77, less than or equal to about 0.75, less than or equal to about 0.73, less than or equal to about 0.7, less than or equal to about 0.69, less than or equal to about 0.68, less than or equal to about 0.67, less than or equal to about 0.66, less than or equal to about 0.65, less than or equal to about 0.64, less than or equal to about 0.63, less than or equal to about 0.62, or less than or equal to about 0.61.

In the semiconductor nanoparticle, a mole ratio (S/(Se+Te)) of sulfur to a total sum of selenium and tellurium may be greater than or equal to about 0.1, greater than or equal to about 0.2, greater than or equal to about 0.3, greater than or equal to about 0.35, greater than or equal to about 0.4, greater than or equal to about 0.45, greater than or equal to about 0.5, greater than or equal to about 0.55, greater than or equal to about 0.59, greater than or equal to about 0.6, or greater than or equal to about 0.61. In the semiconductor nanoparticle, the mole ratio (S/(Se+Te)) of sulfur to a total sum of selenium and tellurium may be less than or equal to about 1.5, less than or equal to about 1.4, less than or equal to about 1.3, less than or equal to about 1.2, less than or equal to about 1, less than or equal to about 0.9, less than or equal to about 0.8, less than or equal to about 0.77, less than or equal to about 0.75, less than or equal to about 0.73, less than or equal to about 0.7, less than or equal to about 0.69, less than or equal to about 0.68, less than or equal to about 0.67, less than or equal to about 0.66, less than or equal to about 0.65, less than or equal to about 0.64, less than or equal to about 0.63, less than or equal to about 0.62, or less than or equal to about 0.61.

In the semiconductor nanoparticle, a mole ratio (Zn/(Se+S+Te)) of zinc to a total sum of selenium, sulfur, and tellurium may be greater than or equal to about 0.8, greater than or equal to about 0.9, or greater than or equal to about 1. In the semiconductor nanoparticle, the mole ratio of zinc to a total sum of selenium, sulfur, and tellurium may be less than or equal to about 2, less than or equal to about 1.5, or less than or equal to about 1.3.

In the semiconductor nanoparticle, a mole ratio (Zn/(Se+S)) of zinc to a total sum of selenium and sulfur may be greater than or equal to about 0.8, greater than or equal to about 0.9, or greater than or equal to about 1. In the semiconductor nanoparticle, the mole ratio of zinc to a total sum of selenium and sulfur may be less than or equal to about 2, less than or equal to about 1.5, or less than or equal to about 1.3.

Within the semiconductor nanoparticle or semiconductor nanocrystal shell of an embodiment, a content of the metal dopant may be such that the third semiconductor nanocrystal or zinc sulfide-containing nanocrystal may maintain a zinc blende lattice structure. In an embodiment, a content of the metal dopant relative to the total cation metal (e.g., zinc) within the semiconductor nanoparticle or within the semiconductor nanocrystal shell may be less than or equal to about 30 at %, less than or equal to about 25 at %, less than or equal to about 20 at %, less than or equal to about 15 at %, less than or equal to about 10 at %, less than or equal to about 9 at %, less than or equal to about 8 at %, less than or equal to about 7 at %, less than or equal to about 6 at %, less than or equal to about 5 at %, less than or equal to about 4 at %, less than or equal to about 3 at %, less than or equal to about 2 at %, less than or equal to about 1 at %, or less than or equal to about 0.5 at %. If the metal dopant is bound to the surface of the semiconductor nanoparticle, the content of the metal dopant identified in the analysis of the semiconductor nanoparticle may increase. Within the semiconductor nanoparticle or within the semiconductor nanocrystal shell, the content of the metal dopant may be greater than or equal to about 0.001 at %, greater than or equal to about 0.005 at %, greater than or equal to about 0.008 at %, greater than or equal to about 0.01 at %, greater than or equal to about 0.03 at %, greater than or equal to about 0.05 at %, greater than or equal to about 0.08 at %, greater than or equal to about 0.1 at %, greater than or equal to about 0.2 at %, greater than or equal to about 0.3 at %, greater than or equal to about 0.5 at %, greater than or equal to about 0.7 at %, greater than or equal to about 0.9 at %, or greater than or equal to about 1 at % relative to the total cation.

In the semiconductor nanoparticle, a mole ratio of the metal dopant to tellurium (metal dopant/tellurium) may be greater than or equal to about 0.0001, greater than or equal to about 0.0005, greater than or equal to about 0.001, greater than or equal to about 0.003, greater than or equal to about 0.005, greater than or equal to about 0.007, greater than or equal to about 0.01, greater than or equal to about 0.03, greater than or equal to about 0.05, greater than or equal to about 0.07, greater than or equal to about 0.1, greater than or equal to about 0.3, greater than or equal to about 0.5, greater than or equal to about 0.7, greater than or equal to about 0.9, greater than or equal to about 1, greater than or equal to about 3, greater than or equal to about 5, or greater than or equal to about 7. In the semiconductor nanoparticle, the mole ratio of the metal dopant to tellurium (metal dopant/tellurium) may be less than or equal to about 100, less than or equal to about 80, less than or equal to about 60, less than or equal to about 55, less than or equal to about 50, less than or equal to about 45, less than or equal to about 40, less than or equal to about 35, less than or equal to about 30, less than or equal to about 25, less than or equal to about 20, less than or equal to about 19, or less than or equal to about 10.

In the semiconductor nanoparticle, a mole ratio of zinc to the metal dopant (zinc/metal dopant) may be greater than or equal to about 10, greater than or equal to about 15, greater than or equal to about 20, greater than or equal to about 50, greater than or equal to about 100, or greater than or equal to about 250. In the semiconductor nanoparticle, the mole ratio of zinc to the metal dopant (zinc/metal dopant) may be less than or equal to about 1500, less than or equal to about 1000, or less than or equal to about 800.

In the semiconductor nanoparticle, a mole ratio of the metal dopant to a total sum of zinc and the metal dopant ((metal dopant/(Zn+metal dopant)) may be greater than or equal to about 0.0001, greater than or equal to about 0.0005, greater than or equal to about 0.0008, greater than or equal to about 0.001, greater than or equal to about 0.002, greater than or equal to about 0.003, greater than or equal to about 0.004, greater than or equal to about 0.005, greater than or equal to about 0.006, greater than or equal to about 0.007, greater than or equal to about 0.008, greater than or equal to about 0.009, greater than or equal to about 0.01, greater than or equal to about 0.02, greater than or equal to about 0.03, greater than or equal to about 0.04, greater than or equal to about 0.05, greater than or equal to about 0.06, greater than or equal to about 0.07, greater than or equal to about 0.08, greater than or equal to about 0.09, greater than or equal to about 0.1, greater than or equal to about 0.3, greater than or equal to about 0.5, or greater than or equal to about 0.7. In the semiconductor nanoparticle, the mole ratio of the metal dopant to a total sum of zinc and the metal dopant ((metal dopant/(Zn+metal dopant)) may be less than or equal to about 0.9, less than or equal to about 0.8, less than or equal to about 0.7, less than or equal to about 0.6, less than or equal to about 0.5, less than or equal to about 0.4, less than or equal to about 0.3, less than or equal to about 0.2, less than or equal to about 0.1, less than or equal to about 0.09, less than or equal to about 0.08, less than or equal to about 0.07, less than or equal to about 0.06, less than or equal to about 0.05, or less than or equal to about 0.04.

In the semiconductor nanoparticle, a mole ratio of the metal dopant to zinc (metal dopant/Zn) may be greater than or equal to about 0.0001, greater than or equal to about 0.0005, greater than or equal to about 0.0008, greater than or equal to about 0.001, greater than or equal to about 0.002, greater than or equal to about 0.003, greater than or equal to about 0.004, greater than or equal to about 0.005, greater than or equal to about 0.006, greater than or equal to about 0.007, greater than or equal to about 0.008, greater than or equal to about 0.009, greater than or equal to about 0.01, greater than or equal to about 0.02, greater than or equal to about 0.03, greater than or equal to about 0.04, greater than or equal to about 0.05, greater than or equal to about 0.06, greater than or equal to about 0.07, greater than or equal to about 0.08, greater than or equal to about 0.09, greater than or equal to about 0.1, greater than or equal to about 0.2, greater than or equal to about 0.3, greater than or equal to about 0.4, greater than or equal to about 0.5, greater than or equal to about 0.6, or greater than or equal to about 0.7. In the semiconductor nanoparticle, the mole ratio of the metal dopant to zinc (metal dopant/Zn) may be less than or equal to about 0.9, less than or equal to about 0.8, less than or equal to about 0.7, less than or equal to about 0.6, less than or equal to about 0.55, less than or equal to about 0.5, less than or equal to about 0.45, less than or equal to about 0.4, less than or equal to about 0.3, less than or equal to about 0.2, less than or equal to about 0.1, less than or equal to about 0.09, less than or equal to about 0.085, less than or equal to about 0.08, less than or equal to about 0.075, less than or equal to about 0.07, less than or equal to about 0.065, less than or equal to about 0.06, less than or equal to about 0.055, less than or equal to about 0.05, less than or equal to about 0.045, or less than or equal to about 0.04.

In the semiconductor nanoparticle according to an embodiment, a mole ratio of the metal dopant (e.g., aluminum, gallium, zirconium, magnesium, or a combination thereof) to sulfur (metal dopant/sulfur) may be greater than or equal to about 0.005, greater than or equal to about 0.01, greater than or equal to about 0.03, greater than or equal to about 0.05, greater than or equal to about 0.08, greater than or equal to about 0.1, greater than or equal to about 0.12, greater than or equal to about 0.14, greater than or equal to about 0.15, or greater than or equal to about 0.17. In the semiconductor nanoparticle according to an embodiment, the a mole ratio of the metal dopant to sulfur (metal dopant/sulfur) may be less than or equal to about 0.5, less than or equal to about 0.4, less than or equal to about 0.3, less than or equal to about 0.2, less than or equal to about 0.1, less than or equal to about 0.09, less than or equal to about 0.08, less than or equal to about 0.07, less than or equal to about 0.06, less than or equal to about 0.05, less than or equal to about 0.04, less than or equal to about 0.03, less than or equal to about 0.02, or less than or equal to about 0.01. In an embodiment, the metal dopant may include aluminum, and in the semiconductor nanoparticle, the mole ratio of aluminum to sulfur (aluminum/sulfur) may be less than or equal to about 0.09. In an embodiment, the metal dopant may include aluminum, and in the semiconductor nanoparticle, the mole ratio of aluminum to sulfur (aluminum/sulfur) may be greater than or equal to about 0.001 and less than or equal to about 0.4. The metal dopant may include gallium, and in the semiconductor nanoparticle, the mole ratio of gallium to sulfur (gallium/sulfur) may be greater than or equal to about 0.1, or greater than or equal to about 0.14. The metal dopant may include gallium, and in the semiconductor nanoparticle, the mole ratio of gallium to sulfur (gallium/sulfur) may be greater than or equal to about 0.01 and less than or equal to about 0.1. The metal dopant may include zirconium, and in the semiconductor nanoparticle, the mole ratio of zirconium to sulfur (zirconium/sulfur) may be greater than or equal to about 0.05, or greater than or equal to about 0.09. The metal dopant may include zirconium, and in the semiconductor nanoparticle, the mole ratio of zirconium to sulfur (zirconium/sulfur) may be greater than or equal to about 0.01 and greater than or equal to about 0.4.

The mole ratio between the elements in this specification may be confirmed by appropriate analytical means (e.g., inductively coupled plasma-atomic emission spectroscopy (ICP-AES), X-ray photoelectron spectroscopy (XPS), electron microscopy-energy dispersive spectroscopy (TEM-EDX or SEM-EDX), scanning electron microscopy-energy dispersive spectroscopy (SEM-EDX), X-ray fluorescence (XRF), or the like).

The semiconductor nanoparticle of an embodiment may have the size described herein. As used herein, the size may refer to individual particle size or average size of particles. The size may be a diameter of the particle or an equivalent diameter calculated assuming a sphere.

A (average) size of the semiconductor nanoparticle may be greater than or equal to about 8 nm, greater than or equal to about 8.5 nm, greater than or equal to about 9 nm, greater than or equal to about 9.5 nm, greater than or equal to about 10 nm, greater than or equal to about 10.5 nm, greater than or equal to about 11 nm, greater than or equal to about 11.5 nm, greater than or equal to about 12 nm, greater than or equal to about 12.5 nm, greater than or equal to about 12.8 nm, greater than or equal to about 13 nm, greater than or equal to about 13.5 nm, greater than or equal to about 14 nm, or greater than or equal to about 14.2 nm. A (average) size of the nanoparticle(s) may be less than or equal to about 50 nm, for example, less than or equal to about 40 nm, less than or equal to about 35 nm, less than or equal to about 29 nm, less than or equal to about 28 nm, less than or equal to about 27 nm, less than or equal to about 26 nm, less than or equal to about 25 nm, less than or equal to about 24 nm, less than or equal to about 23 nm, less than or equal to about 22 nm, less than or equal to about 21 nm, less than or equal to about 20 nm, less than or equal to about 19 nm, less than or equal to about 18 nm, less than or equal to about 17.5 nm, less than or equal to about 17 nm, less than or equal to about 16.5 nm, less than or equal to about 16 nm, less than or equal to about 15.5 nm, less than or equal to about 15 nm, less than or equal to about 14.5 nm, less than or equal to about 14 nm, less than or equal to about 13.5 nm, less than or equal to about 13 nm, less than or equal to about 12.5 nm, less than or equal to about 12 nm, or less than or equal to about 11.5 nm. As used herein, the average may be a mean. As used herein, the mean may be a median. The numerical values set forth in this specification may include approximate values. The semiconductor nanoparticle may have a particle size of greater than or equal to about 9 nm, greater than or equal to about 10 nm, or greater than or equal to about 12 nm and less than or equal to about 50 nm.

The semiconductor nanoparticle of an embodiment may have a particle size distribution (or standard deviation of particle size) of less than or equal to about 15%, less than or equal to about 14%, less than or equal to about 13%, less than or equal to about 12%, or less than or equal to about 11%. The particle size distribution may greater than or equal to about 1%, greater than or equal to about 5%, or greater than or equal to about 7%.

The size of the particle may be easily and reproducibly determined (according to the manual provided by the manufacturer, or the like) from photographs of the particle obtained by electron microscopy (e.g., scanning electron microscopy or transmission electron microscopy) analysis using a known or commercially available image analysis tool (e.g., Image J). The image analysis tools and measurement conditions are not particularly limited.

In an embodiment, the semiconductor nanoparticle may have a core-shell structure. The semiconductor nanoparticle may include a core; and a semiconductor nanocrystal shell disposed on the core. The core may include the first zinc chalcogenide (or the first semiconductor nanocrystal). In an embodiment, the first semiconductor nanocrystal or the core may include a first zinc chalcogenide including zinc, selenium, and tellurium. The size or average size (hereinafter, abbreviated as “size”) of the core may be greater than or equal to about 2 nm, greater than or equal to about 2.5 nm, greater than or equal to about 3 nm, greater than or equal to about 3.5 nm, greater than or equal to about 4 nm, or greater than or equal to about 4.5 nm. The size of the core may be less than or equal to about 6 nm, for example, less than or equal to about 5 nm. The size of the core may be about 2 nm to about 6 nm, or about 2.5 nm to about 5 nm. The first semiconductor nanocrystal may include ZnTeₓSe₁₋ₓ (wherein, x is greater than 0, greater than or equal to about 0.001, greater than or equal to about 0.003, greater than or equal to about 0.005, greater than or equal to about 0.007, greater than or equal to about 0.009, greater than or equal to about 0.01, greater than or equal to about 0.03, greater than or equal to about 0.05, greater than or equal to about 0.09 and less than or equal to about 0.1, less than or equal to about 0.05, less than or equal to about 0.04, less than or equal to about 0.03, less than or equal to about 0.02, less than or equal to about 0.01, or less than or equal to about 0.008). The core may or may not further include sulfur.

The semiconductor nanocrystal shell is different from the first semiconductor nanocrystal and may include zinc, selenium, and sulfur. In the semiconductor nanoparticle, the semiconductor nanocrystal shell or the semiconductor nanocrystal included therein may include zinc, selenium, and sulfur (or a zinc chalcogenide including the same). The semiconductor nanocrystal shell may or may not include tellurium. The semiconductor nanocrystal shell (or each layer in the multilayer shell described herein) may be a gradient alloy having a composition that varies in the radial direction. In an embodiment, the content of sulfur within the semiconductor nanocrystal shell may increase toward the surface of the semiconductor nanoparticle. For example, in the semiconductor nanocrystal shell, the content of sulfur may have a concentration gradient that increases with distance from the core.

The semiconductor nanocrystal shell may be a multilayer shell including a plurality of layers. In a multilayer shell, adjacent layers may include semiconductor materials of different compositions. The multilayer shell may include a middle shell layer on the core (e.g., directly on the core) and an outer shell layer (or referred to as an outer layer) on the middle shell layer. In other words, the second semiconductor nanocrystal (or the middle shell layer) may be disposed between the first semiconductor nanocrystal (or the core) and the third semiconductor nanocrystal (or the outer layer).

In an embodiment, the semiconductor nanocrystal shell may include a second semiconductor nanocrystal (or a middle shell layer including the second semiconductor nanocrystal) including a second zinc chalcogenide including zinc and selenium, and a third semiconductor nanocrystal (or an outer layer including the third semiconductor nanocrystal) including a third zinc chalcogenide including zinc and sulfur. The second zinc chalcogenide may have a different composition from the third zinc chalcogenide.

The middle shell layer or the second semiconductor nanocrystal may include zinc, selenium, and optionally sulfur. The second zinc chalcogenide may or may not further include sulfur. The middle shell layer or the second semiconductor nanocrystal may include ZnSe, ZnSeS, or a combination thereof. The outer shell layer or the third semiconductor nanocrystal may include zinc, sulfur, and optionally selenium. The outer shell layer or the third semiconductor nanocrystal may include ZnS, ZnSSe, or a combination thereof. The third zinc chalcogenide may or may not further include selenium. The outer layer may be the outermost layer of the semiconductor nanoparticle. In the semiconductor nanoparticle according to an embodiment, a thickness of the second semiconductor nanocrystal (or the middle shell layer) may be greater than or equal to about 1 nm, greater than or equal to about 1.2 nm, greater than or equal to about 1.5 nm, greater than or equal to about 1.8 nm, greater than or equal to about 2 nm, greater than or equal to about 2.1 nm, greater than or equal to about 2.2 nm, greater than or equal to about 2.3 nm, greater than or equal to about 2.4 nm, greater than or equal to about 2.5 nm, greater than or equal to about 2.6 nm, greater than or equal to about 2.7 nm, greater than or equal to about 2.8 nm, greater than or equal to about 2.9 nm, greater than or equal to about 3 nm, greater than or equal to about 3.1 nm, greater than or equal to about 3.2 nm, greater than or equal to about 3.3 nm, greater than or equal to about 3.4 nm, greater than or equal to about 3.5 nm, greater than or equal to about 3.6 nm, greater than or equal to about 3.7 nm, greater than or equal to about 3.8 nm, greater than or equal to about 3.9 nm, greater than or equal to about 4 nm, greater than or equal to about 4.1 nm, greater than or equal to about 4.2 nm, greater than or equal to about 4.3 nm, greater than or equal to about 4.4 nm, greater than or equal to about 4.5 nm, greater than or equal to about 4.6 nm, greater than or equal to about 4.7 nm, greater than or equal to about 4.8 nm, greater than or equal to about 4.9 nm, greater than or equal to about 5 nm, greater than or equal to about 5.1 nm, or greater than or equal to about 5.2 nm. The thickness of the second semiconductor nanocrystal (or the middle shell layer) may be less than or equal to about 6.5 nm, less than or equal to about 6 nm, less than or equal to about 5.9 nm, less than or equal to about 5.8 nm, less than or equal to about 5.7 nm, less than or equal to about 5.6 nm, less than or equal to about 5.5 nm, less than or equal to about 5.4 nm, less than or equal to about 5.3 nm, less than or equal to about 5.2 nm, less than or equal to about 5.1 nm, less than or equal to about 5 nm, less than or equal to about 4.9 nm, less than or equal to about 4.8 nm, less than or equal to about 4.7 nm, less than or equal to about 4.6 nm, less than or equal to about 4.5 nm, less than or equal to about 4.4 nm, less than or equal to about 4.3 nm, less than or equal to about 4.2 nm, less than or equal to about 4 nm, less than or equal to about 3.4 nm, less than or equal to about 3.1 nm, less than or equal to about 2.8 nm, less than or equal to about 2.7 nm, less than or equal to about 2.6 nm, less than or equal to about 2.5 nm, or less than or equal to about 2.3 nm.

In the semiconductor nanoparticle according to an embodiment, a thickness of the third semiconductor nanocrystal (or the outer layer, e.g., ZnS layer) may be greater than or equal to about 0.2 nm, greater than or equal to about 0.23 nm, greater than or equal to about 0.25 nm, greater than or equal to about 0.27 nm, greater than or equal to about 0.31 nm, greater than or equal to about 0.33 nm, greater than or equal to about 0.35 nm, greater than or equal to about 0.37 nm, greater than or equal to about 0.39 nm, greater than or equal to about 0.41 nm, greater than or equal to about 0.43 nm, greater than or equal to about 0.45 nm, greater than or equal to about 0.47 nm, greater than or equal to about 0.49 nm, greater than or equal to about 0.5 nm, greater than or equal to about 0.7 nm, greater than or equal to about 0.9 nm, greater than or equal to about 1.1 nm, greater than or equal to about 1.3 nm, greater than or equal to about 1.5 nm, greater than or equal to about 1.7 nm, greater than or equal to about 1.8 nm, or greater than or equal to about 2 nm. The thickness of the third semiconductor nanocrystal (or the outer layer) may be less than or equal to about 3 nm, less than or equal to about 2.5 nm, less than or equal to about 1.2 nm, less than or equal to about 1.1 nm, less than or equal to about 1 nm, less than or equal to about 0.9 nm, or less than or equal to about 0.8 nm.

In the semiconductor nanoparticle according to an embodiment, a thickness of the semiconductor nanocrystal shell may be greater than or equal to about 1.5 nm, greater than or equal to about 2 nm, greater than or equal to about 2.5 nm, greater than or equal to about 3 nm, greater than or equal to about 3.5 nm, greater than or equal to about 3.8 nm, greater than or equal to about 3.9 nm, greater than or equal to about 4 nm, greater than or equal to about 4.2 nm, greater than or equal to about 4.5 nm, greater than or equal to about 4.8 nm, greater than or equal to about 5 nm, greater than or equal to about 5.2 nm, greater than or equal to about 5.4 nm, or greater than or equal to about 5.5 nm. The thickness of the semiconductor nanocrystal shell may be less than or equal to about 20 nm, less than or equal to about 15 nm, less than or equal to about 10 nm, less than or equal to about 8 nm, less than or equal to about 7 nm, less than or equal to about 6 nm, less than or equal to about 5.7 nm, less than or equal to about 5.5 nm, less than or equal to about 5 nm, or less than or equal to about 4.5 nm.

In the semiconductor nanoparticle, the metal dopant may be included in the third semiconductor nanocrystal. The metal dopant may be included within the third semiconductor nanocrystal, for example within the crystal lattice or between adjacent lattices, or may be disposed on the surface of the semiconductor nanoparticle.

The semiconductor nanoparticle may or may not further include indium, copper, or a combination thereof. The semiconductor nanoparticle may or may not further include indium phosphide, copper indium sulfide, or a combination thereof. The semiconductor nanoparticle may or may not further include a Group 11-13 compound, a Group Nov. 13, 2016 compound, or a combination thereof.

In an embodiment, the semiconductor nanoparticle may be produced according to the method described herein. In an embodiment, a method of producing the semiconductor nanoparticle includes admixing a particle including zinc, selenium, and tellurium, a zinc precursor, and a sulfur precursor into a reaction medium; and the heating the reaction medium to a reaction temperature, wherein, in the method, the sulfur precursor comprises a product from a reaction between a metal dopant compound and an organic thiol compound, the metal dopant compound comprises aluminum, magnesium, gallium, zirconium, hafnium, or a combination thereof, the reaction of the metal dopant compound and the organic thiol compound is performed at a first temperature of less than 100° C., and the reaction temperature is greater than or equal to about 245° C. and less than or equal to about 400° C. In embodiments, the metal dopant compound may include a trialkyl aluminum, a dialkyl magnesium, a zirconium alkoxide, a gallium alkoxide, a hafnium alkoxide, or a combination thereof. The reaction of the metal dopant compound and the organic thiol compound may include contacting the metal dopant compound and the organic thiol compound at a temperature (e.g., the first temperature) of less than or equal to about 90° C. or less than or equal to about 50° C., and may not involve separate heating. The contacting may be accompanied by an exothermic reaction. A metal thiolate may be formed by a reaction between the metal dopant compound and the organic thiol compound.

By the admixing and heating, the zinc precursor and the sulfur precursor may react in the presence of the particle to form a semiconductor nanocrystal layer (or outermost layer). The sulfur precursor may not include sulfur-TOP. The reaction medium may include an organic solvent and optionally an organic ligand. The reaction medium may be vacuum treated at a predetermined temperature (e.g., a temperature of greater than or equal to 100° C. and less than or equal to about 200° C.).

In the case of conventional technology, a metal compound including an alkoxide moiety is used as a metal dopant compound during ZnS shelling. However, the present inventors have found that, in the case of semiconductor nanoparticle including zinc, selenium, and tellurium is configured to emit blue light, an electroluminescence life-span characteristic cannot be obtained using such a conventional technique. In the method of an embodiment, a metal dopant compound having relatively high reactivity is reacted with a thiol compound to generate a sulfur precursor, which is then reacted with a zinc precursor in the presence of a first semiconductor nanocrystal-containing particle to form a zinc sulfide-containing shell layer on the particle.

The semiconductor nanoparticle may include a first zinc chalcogenide (or a first semiconductor nanocrystal including the first zinc chalcogenide) including zinc, selenium, and tellurium. The semiconductor nanoparticle may include a second zinc chalcogenide (or a second semiconductor nanocrystal including the second zinc chalcogenide) including zinc, selenium, and optionally sulfur. The second semiconductor nanocrystal may be disposed on the first semiconductor nanocrystal.

The formation of the semiconductor nanoparticle is not particularly limited and may be appropriately selected. In an embodiment, the first semiconductor nanocrystal or the core including the first semiconductor nanocrystal may or may not include zinc and selenium, and optionally tellurium. The first semiconductor nanocrystal or the core including the first semiconductor nanocrystal may or may not include indium phosphide. In an embodiment, the first semiconductor nanoparticle or the core including the first semiconductor nanoparticle may be produced by an appropriate method or obtained commercially, considering the composition and desired property of the final nanoparticle.

In an embodiment, the first semiconductor nanocrystal or core includes a zinc chalcogenide including zinc, selenium, and tellurium, and the first semiconductor nanocrystal or the core may be obtained by: preparing a zinc precursor solution including a zinc precursor and an organic ligand; preparing a selenium precursor and a tellurium precursor; heating the zinc precursor solution to a reaction temperature for core formation, adding the selenium precursor and the tellurium precursor, optionally together with an organic ligand, and performing a core formation reaction. In an embodiment, the first semiconductor nanocrystal or a core including the first semiconductor nanocrystal may be formed by a hot injection method in which a non-metal precursor is injected into a solution including a metal precursor and optionally a ligand while the solution is heated to a high temperature (e.g., a temperature of greater than or equal to about 200° C.). In an embodiment, the core may also be produced by a heating method of injecting a non-metal precursor at a predetermined temperature and raising the temperature of the reaction system.

In the core formation reaction, a ratio between each precursor (e.g., a mole ratio of the tellurium precursor to the selenium precursor) or the reaction time may be appropriately selected considering the emission wavelength of the final semiconductor nanoparticle, the reactivity of the precursor, the reaction temperature, or the like. The reaction temperature for core formation may be appropriately selected. The reaction temperature for core formation may be greater than or equal to about 240° C., greater than or equal to about 250° C., greater than or equal to about 260° C., greater than or equal to about 270° C., or greater than or equal to about 280° C., for example, greater than or equal to about 290° C. The reaction temperature for core formation may be in the range of about 280° C. to about 340° C., for example, about 290° C. to about 330° C., or about 300° C. to about 320° C. The reaction time for core formation may be adjusted considering the desired core size and the reactivity of the precursor and is not particularly limited. For example, the reaction time may be greater than or equal to about 5 minutes, greater than or equal to about 30 minutes, or greater than or equal to about 50 minutes, but is not limited thereto. For example, the reaction time may be less than or equal to about 2 hours, but is not limited thereto. The formed core may or may not be separated from the reaction system (e.g., by nonsolvent precipitation). The separated core may be optionally washed and added to subsequent reactions.

The semiconductor nanoparticle of an embodiment may further include a second semiconductor nanocrystal or a middle shell including the second semiconductor nanocrystal, and the method for forming the second semiconductor nanocrystal or the middle shell layer including the second semiconductor nanocrystal is not particularly limited and may be appropriately selected.

In the method of an embodiment, the forming of the second semiconductor nanocrystal (or the middle shell layer including the second semiconductor nanocrystal) on the first semiconductor nanocrystal includes contacting (reacting) a zinc precursor and a chalcogen precursor (e.g., a selenium precursor and optionally a sulfur precursor) at a reaction temperature in the presence of an organic solvent and the first semiconductor nanocrystal. The particle including the first semiconductor nanocrystal and optionally the second semiconductor nanocrystal may be separated and washed according to the method described herein after synthesis and prior to being subjected to a subsequent reaction (e.g., a reaction to form a semiconductor nanocrystal shell including zinc and sulfur). The separated and washed particle may be dispersed in a suitable organic solvent (e.g., an aromatic solvent such as toluene or an aliphatic hydrocarbon solvent such as octane) and added to a subsequent reaction.

The metal dopant compound is believed to have increased reactivity and may react with organic thiol (e.g., alkyl thiol), thereby forming a metal-thiolate compound. The metal dopant compound having relatively high reactivity may readily react with the organic thiol compound even at temperatures of less than or equal to about 100° C., for example, less than or equal to about 80° C., less than or equal to about 60° C., or less than or equal to about 50° C. The metal dopant compound may undergo an exothermic reaction with the organic thiol compound at a temperature of greater than or equal to about 30° C. and less than or equal to about 50° C.

The metal dopant compound may include a moiety bonded to a central metal, wherein the moiety may include a substituted or unsubstituted C1-C30 or C2-C8 or C3-C5 hydrocarbon group, a substituted or unsubstituted C1-C30 or C2-C8 or C3-C5 amino group (e.g., an alkyl amino group), or a combination thereof, and the central metal may include aluminum, magnesium, gallium, zirconium, hafnium, or a combination thereof. The metal dopant compound may not include an alkoxide moiety. The metal dopant compound may include a compound represented by Chemical Formula 1:

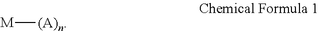

As used herein, M is aluminum, magnesium, gallium, zirconium, or hafnium, A is a substituted or unsubstituted C1-C30, C2-C8 or C3-C5 aliphatic hydrocarbon group (e.g., an alkyl group such as methyl, ethyl, propyl, isopropyl, butyl, isobutyl, or the like, an alkenyl group, or an alkynyl group), a substituted or unsubstituted C6-C20 aromatic hydrocarbon group (e.g., a phenyl group), a substituted or unsubstituted C1-C30, C2-C8 or C3-C5 amino group (e.g., a dimethylamino group), or a combination thereof, and n is a number determined according to a valence of the metal M and is an integer from 2 to 4.

The organic thiol compound may include a hydrocarbon group of C3-C30, C5-C20, C8-C18, or C10-C12 (e.g., an aliphatic hydrocarbon group, an aromatic hydrocarbon group, or an alicyclic hydrocarbon group). The organic thiol compound may include a monothiol compound, a polythiol compound, or a combination thereof.

In the metal dopant compound or the organic thiol, the hydrocarbon group may include a (linear or branched) aliphatic hydrocarbon group, an aromatic hydrocarbon group, or a combination thereof. The hydrocarbon group may or may not further include oxygen, nitrogen, or a combination thereof.

The aliphatic hydrocarbon group may include an alkyl group, an alkenyl group, or an alkynyl group. The (aliphatic) hydrocarbon group may include methyl, ethyl, propyl, butyl, pentyl, hexyl, or a combination thereof.

The metal dopant compound may include an alkylaluminum compound such as trimethylaluminum, triethylaluminum, methyldiethylaluminum, dimethylethylaluminum, triisopropylaluminum, tributylaluminum, or the like, a trialkylgallium such as trimethylgallium, triethylgallium, or the like, or a combination thereof.

The thiol compound may be an alkyl thiol compound. The alkyl length of the alkyl thiol compound may be a carbon chain structure having 6 to 14 carbon atoms, and desirably, dodecane thiol having 12 carbon atoms or octyl thiol having 8 carbon atoms may be used. Thiol with a branched alkyl chain structure rather than a linear carbon chain structure may also be used.

A mole ratio between the metal dopant compound and the thiol compound may be appropriately selected by considering a valence of the metal dopant, or the like The mole ratio between the metal dopant compound and the thiol compound (metal dopant compound:thiol compound) may be in the range of about 1:0.08 to about 1:22, about 1:0.1 to about 1:20, about 1:0.2 to about 1:18, about 1:0.25 to about 1:17, about 1:0.3 to about 1:16, about 1:0.35 to about 1:15, about 1:0.4 to about 1:13, about 1:0.45 to about 1:12, about 1:0.5 to about 1:10, about 1:0.55 to about 1:9, about 1:0.6 to about 1:8, about 1:0.65 to about 1:7, about 1:0.7 to about 1:5, about 1:0.75 to about 1:4, about 1:0.8 to about 1:3, about 1:0.85 to about 1:1.25, about 1:0.9 to about 1:1.2, or about 1:1 to about 1:1.1.

In an embodiment, when a molar content of the sulfur precursor is about 0.4 to about 1.5, the molar content of the metal dopant may be in the range of about 0.05 to about 1, about 0.1 to about 0.8, about 0.3 to about 0.7, or about 0.5 to about 0.6, or a combination thereof.

An order of adding the particle, the zinc precursor, and the sulfur precursor is not particularly limited and may be appropriately selected. The admixing may be performed one or more times, or two or more times. In an embodiment, the zinc precursor and the sulfur precursor may be injected into the reaction medium twice or more.

The organic ligand, organic solvent, zinc precursor, selenium precursor, and tellurium precursor are not particularly limited and may be appropriately selected.

The organic solvent may include a C6 to C22 primary amine such as hexadecylamine, a C6 to C22 secondary amine such as dioctylamine, a C6 to C40 tertiary amine such as trioctylamine, a nitrogen-containing heterocyclic compound such as pyridine, a C6 to C40 olefin such as octadecene, a C6 to C40 aliphatic hydrocarbon such as hexadecane, octadecane, and squalane, an aromatic hydrocarbon substituted with a C6 to C30 alkyl group such as phenyldodecane, phenyltetradecane, and phenyl hexadecane, a primary, secondary, or tertiary phosphine substituted with at least one (e.g., 1, 2, or 3) C6 to C22 alkyl group (e.g., trioctylamine), a phosphine oxide (e.g., trioctylphosphine oxide) substituted with (e.g., 1, 2, or 3) C6 to C22 alkyl groups, C12 to C22 aromatic ether such as phenyl ether, benzyl ether, or a combination thereof.

The organic ligand coordinates the surface of the produced semiconductor nanoparticle and may enable the semiconductor nanoparticle to be well dispersed in a solution. The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH (wherein, R and R′ are each independently C1 or more, C6 or more, or C10 or more and C40 or less, C35 or less, or C25 or less substituted or unsubstituted aliphatic hydrocarbon, or C6 to C40 substituted or unsubstituted aromatic hydrocarbon, or a combination thereof), or a combination thereof. The ligand may be used alone or as a combination of two or more compounds.

Examples of the organic ligand may include a thiol compound such as methanethiol, ethanethiol, propanethiol, butanethiol, pentanethiol, hexanethiol, octanethiol, dodecanethiol, hexadecanethiol, octadecanethiol, and benzylthiol; amines such as methane amine, ethane amine, propan amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributyl amine, and trioctyl amine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, myristic acid, stearic acid, lauric acid, and benzoic acid; a phosphine compound such as methyl phosphine, ethyl phosphine, propyl phosphine, butyl phosphine, pentyl phosphine, octylphosphine, dioctyl phosphine, tributylphosphine, and trioctylphosphine; a phosphine compound such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, trioctylphosphine oxide, and diphenylphosphine (DPP) or an oxide compound thereof; diphenylphosphine; a triphenylphosphine compound, or an oxide compound thereof; a C5 to C20 alkyl phosphinic acid such as hexylphosphinic acid, octylphosphinic acid, dodecanephosphinic acid, tetradecanephosphinic acid, hexadecanephosphinic acid, and octadecanephosphinic acid or a C5 to C20 alkyl phosphonic acid; but are not limited thereto.

The zinc precursor may include Zn metal powder, ZnO, an alkylated Zn compound (e.g., a C2 to C30 dialkylzinc such as diethylzinc), Zn alkoxide (e.g., zinc ethoxide), Zn carboxylate (e.g., zinc acetate), Zn nitrate, Zn perchlorate, Zn sulfate, Zn acetylacetonate, Zn halide (e.g., zinc chloride), Zn cyanide, Zn hydroxide, zinc carbonate, zinc peroxide, or a combination thereof. Examples of the zinc precursor may include dimethyl zinc, diethyl zinc, zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, and a combination thereof.

The selenium precursor may include selenium-trioctylphosphine (Se-TOP), selenium-tributylphosphine (Se-TBP), selenium-triphenylphosphine (Se-TPP), selenium-diphenylphosphine (Se-DPP), or a combination thereof, but is not limited thereto.

The tellurium precursor may include tellurium-tributylphosphine (Te-TBP), tellurium-triphenylphosphine (Te-TPP), tellurium-diphenylphosphine (Te-DPP), or a combination thereof, but is not limited thereto.

The sulfur precursor may or may not further include hexanethiol, octanethiol, decanethiol, dodecanethiol, hexadecanethiol, mercapto propyl silane, sulfur-trioctylphosphine (S-TOP), sulfur-tributylphosphine (S-TBP), sulfur-triphenylphosphine (S-TPP), sulfur-trioctylamine (S-TOA), bistrialkylsilylsulfide bistrialkylsilylalkylsulfide (e.g., bistrimethylsilylmethyl sulfide), ammonium sulfide, sodium sulfide, or a combination thereof.

In the method, the reaction temperature may be greater than or equal to about 250° C., greater than or equal to about 255° C., greater than or equal to about 260° C., greater than or equal to about 265° C., greater than or equal to about 270° C., greater than or equal to about 275° C., greater than or equal to about 280° C., greater than or equal to about 285° C., greater than or equal to about 290° C., greater than or equal to about 295° C., greater than or equal to about 300° C., greater than or equal to about 305° C., greater than or equal to about 310° C., greater than or equal to about 315° C., greater than or equal to about 320° C., or greater than or equal to about 325° C. The reaction temperature may be less than or equal to about 380° C., less than or equal to about 370° C., less than or equal to about 360° C., less than or equal to about 350° C., or less than or equal to about 340° C.

The reaction time may be appropriately selected considering a type of precursor, reaction temperature, and the desired thickness of the ZnS shell layer in the final semiconductor nanoparticle. The reaction time may be greater than or equal to about 10 minutes, greater than or equal to about 15 minutes, greater than or equal to about 20 minutes, greater than or equal to about 25 minutes, greater than or equal to about 30 minutes, greater than or equal to about 35 minutes, or greater than or equal to about 40 minutes. The reaction time may less than or equal to about 200 minutes, less than or equal to about 180 minutes, less than or equal to about 160 minutes, less than or equal to about 140 minutes, less than or equal to about 120 minutes, less than or equal to about 100 minutes, less than or equal to about 90 minutes, or less than or equal to about 80 minutes.

After the reaction is completed, the first semiconductor nanocrystal, or the second semiconductor nanocrystal-containing particle, or the obtained semiconductor nanoparticle may be recovered by pouring it into an excess nonsolvent to remove excess organic matter not coordinated to the surface, and centrifuging the obtained mixture. For example, after the reaction is completed, if a nonsolvent is added to the reaction product, the semiconductor nanoparticles coordinated with the ligand compound may be separated. The nonsolvent may be a polar solvent that is miscible with the solvent used in the core formation and/or shell formation reactions and is not capable of dispersing the produced nanocrystal. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, ethylene glycol, a solvent having a similar solubility parameter to the foregoing solvents, or a combination thereof. The separation may be performed through centrifugation, sedimentation, chromatography, or distillation. The separated nanocrystal may be added to a washing solvent and washed, if needed. The washing solvent has no particular limit and may have a similar solubility parameter to that of the ligand and may, for example, include hexane, heptane, octane, chloroform, toluene, benzene, and the like.

The semiconductor nanoparticle may be non-dispersible or water-insoluble in water, the aforementioned nonsolvent, or a combination thereof. The semiconductor nanoparticles may be dispersed in the aforementioned organic solvent. In an embodiment, the semiconductor nanoparticles may be dispersed in C6 to C40 aliphatic hydrocarbon, C6 to C40 substituted or unsubstituted aromatic hydrocarbon, or a combination thereof.

The obtained semiconductor nanoparticle may exhibit the property described herein.

In an embodiment, the semiconductor nanoparticle, the light emitting layer including the semiconductor nanoparticle, or the electroluminescent device may be configured to emit blue light. For example, the semiconductor nanoparticle may emit blue light upon photoexcitation or voltage application. The blue light or the semiconductor nanoparticle may have a peak emission wavelength (or referred to as a peak luminescence wavelength) (e.g., photoluminescent peak wavelength or electroluminescent peak wavelength) of greater than or equal to about 445 nm and less than or equal to about 480 nm. The peak luminescence wavelength (maximum electroluminescent peak wavelength or maximum photoluminescent peak wavelength) may be in a range of greater than or equal to about 450 nm, greater than or equal to about 452 nm, greater than or equal to about 455 nm, greater than or equal to about 456 nm, greater than or equal to about 457 nm, greater than or equal to about 458 nm, greater than or equal to about 459 nm, greater than or equal to about 460 nm, greater than or equal to about 461 nm, greater than or equal to about 462 nm, greater than or equal to about 463 nm, greater than or equal to about 464 nm, greater than or equal to about 465 nm, greater than or equal to about 466 nm, greater than or equal to about 467 nm, greater than or equal to about 468 nm, greater than or equal to about 469 nm, or greater than or equal to about 470 nm and less than or equal to about 480 nm, less than or equal to about 478 nm, or less than or equal to about 475 nm (e.g., less than or equal to about 470 nm, less than or equal to about 465 nm, less than or equal to about 460 nm, or less than or equal to about 455 nm).

The photoluminescent peak wavelength is the peak emission wavelength of light emitted by a semiconductor nanoparticle or a light emitting layer including the semiconductor nanoparticle upon photoexcitation. The electroluminescent peak wavelength is the peak emission wavelength of light emitted by a semiconductor nanoparticle or a light emitting layer including the semiconductor nanoparticle when voltage is applied.

The semiconductor nanoparticle of an embodiment, when irradiated with light in a solution state or manufactured as a luminescent film, may exhibit a quantum yield (e.g., absolute quantum yield) of greater than or equal to about 70%, greater than or equal to about 75%, greater than or equal to about 76%, greater than or equal to about 77%, greater than or equal to about 78%, greater than or equal to about 79%, greater than or equal to about 80%, greater than or equal to about 81%, greater than or equal to about 82%, greater than or equal to about 83%, greater than or equal to about 84%, greater than or equal to about 85%, greater than or equal to about 86%, greater than or equal to about 87%, greater than or equal to about 88%, or greater than or equal to about 89%. The semiconductor nanoparticle may exhibit a quantum yield in the range of about 76% to about 100%, about 80% to about 99%, about 84% to about 97%, about 86% to about 96%, about 87% to about 95%, about 88% to about 94%, about 89% to about 93%, about 90% to about 92%, or a combination thereof. The quantum yield may be absolute quantum yield or relative quantum yield.

The semiconductor nanoparticle of an embodiment may exhibit a (maximum) luminescent peak having a full width at half maximum of a desired level when voltage is applied or when light is excited. The full width at half maximum may be in a range of about 5 nm to about 55 nm, about 8 nm to about 54 nm, about 9 nm to about 53 nm, about 10 nm to about 52 nm, about 11 nm to about 51 nm, about 12 nm to about 50 nm, about 13 nm to about 49 nm, about 14 nm to about 48 nm, about 15 nm to about 47 nm, about 16 nm to about 46 nm, about 17 nm to about 45 nm, about 18 nm to about 44 nm, about 19 nm to about 43 nm, about 20 nm to about 42 nm, about 21 nm to about 41 nm, about 22 nm to about 40 nm, about 25 nm to about 35 nm, about 28 nm to about 32 nm, or a combination thereof.

The light emitting layer may have an area ratio of the metal dopant to sulfur of greater than or equal to about 0.01, greater than or equal to about 0.05, greater than or equal to about 0.08, greater than or equal to about 0.1, greater than or equal to about 0.12, greater than or equal to about 0.13, greater than or equal to about 0.14, greater than or equal to about 0.15, greater than or equal to about 0.17, greater than or equal to about 0.18, greater than or equal to about 0.19, or greater than or equal to about 0.2 in a depth profile of secondary ion mass spectrometry. The light emitting layer may have an area ratio of the metal dopant to sulfur of less than or equal to about 1, less than or equal to about 0.8, or less than or equal to about 0.7 in a depth profile of secondary ion mass spectrometry.

The light emitting layer may have a ratio of the dopant metal intensity to the S intensity at the center of the (average) thickness of the light emitting layer (for example, 50 seconds when the total thickness is 100 s by sputtering time) as confirmed by a depth profile of secondary ion mass spectrometry of greater than or equal to about 0.01, greater than or equal to about 0.03, greater than or equal to about 0.05, greater than or equal to about 0.08, greater than or equal to about 0.1, greater than or equal to about 0.13, greater than or equal to about 0.15, greater than or equal to about 0.17, greater than or equal to about 0.19, greater than or equal to about 0.2, greater than or equal to about 0.22, greater than or equal to about 0.24, greater than or equal to about 0.25, greater than or equal to about 0.27, greater than or equal to about 0.29, greater than or equal to about 0.3, greater than or equal to about 0.31, greater than or equal to about 0.33, greater than or equal to about 0.35, greater than or equal to about 0.37, greater than or equal to about 0.39, greater than or equal to about 0.4, greater than or equal to about 0.41, greater than or equal to about 0.43, greater than or equal to about 0.45, or greater than or equal to about 0.47. The light emitting layer may have a ratio of the dopant metal intensity to the S intensity at the center of the (average) thickness of the light emitting layer (for example, 50 seconds when the total thickness is 100 s by sputtering time) as confirmed by the depth profile of secondary ion mass spectrometry of less than or equal to about 30, less than or equal to about 20, less than or equal to about 15, less than or equal to about 12, less than or equal to about 10, less than or equal to about 9, less than or equal to about 8, less than or equal to about 7, less than or equal to about 6, less than or equal to about 5, less than or equal to about 4, less than or equal to about 3, less than or equal to about 2, less than or equal to about 1, less than or equal to about 0.9, less than or equal to about 0.8, less than or equal to about 0.7, less than or equal to about 0.6, less than or equal to about 0.5, less than or equal to about 0.45, less than or equal to about 0.4, less than or equal to about 0.35, less than or equal to about 0.3, less than or equal to about 0.25, less than or equal to about 0.2, or less than or equal to about 0.1.

The semiconductor nanoparticle, when included in an electron only device (EOD) having a structure of electrode (e.g., ITO)/ZnMgO metal oxide-containing electron transport layer (thickness approximately 20 nm)/semiconductor nanoparticle-containing light emitting layer (thickness approximately 28 nm)/ZnMgO metal oxide-containing electron transport layer (thickness approximately 20 nm)/electrode (e.g., aluminum), may be configured to exhibit an electron transport ability that is about twice or more (e.g., about 2.5 times or more, about 3 times or more, about 3.5 times or more, about 4 times or more, about 4.5 times or more, about 5 times or more, about 5.5 times or more, about 6 times or more, about 6.5 times or more, about 7 times or more, about 7.5 times or more, about 8 times or more, about 8.5 times or more, about 9 times or more, about 9.5 times or more, or about 10 times or more) as high in current density at 5 volts, for example, in the 3rd sweep compared to semiconductor nanoparticle that does not include the metal dopant.

The semiconductor nanoparticle may exhibit improved light stability.

The semiconductor nanoparticle of an embodiment may form a composition (ink) for an inkjet printing process and provide a light emitting layer pattern through the inkjet printing process. The composition for an inkjet process may include semiconductor nanoparticle and a liquid vehicle, in an embodiment. The semiconductor nanoparticle of an embodiment may form a colloidal dispersion within the liquid vehicle. At least a portion of the liquid vehicle may be removed from the light emitting layer after the inkjet process. The liquid vehicle may include an organic solvent. The organic solvent may include a dispersing solvent as described herein. The organic solvent may be an organic solvent having a relatively high boiling point at normal or atmospheric pressure. The boiling point of the organic solvent or liquid vehicle may be greater than or equal to about 120° C., greater than or equal to about 130° C., greater than or equal to about 140° C., greater than or equal to about 150° C., greater than or equal to about 160° C., greater than or equal to about 170° C., or greater than or equal to about 180° C. The boiling point of the organic solvent may be less than or equal to about 300° C., less than or equal to about 280° C., less than or equal to about 270° C., less than or equal to about 250° C., or less than or equal to about 200° C. The organic solvent may include a substituted or unsubstituted aromatic solvent such as cyclohexylbenzene, a substituted or unsubstituted C6 to C15 aliphatic hydrocarbon solvent such as hexane, octane, decane, or a combination thereof. When using a mixed solvent, the mixing ratio can be adjusted considering a condition for the inkjet process (e.g., boiling point, viscosity, or the like). For example, when using a mixed solvent of an aromatic solvent and an aliphatic solvent, the ratio may be adjusted to about 1:0.1 to about 1:10, about 1:0.3 to about 1:3, about 1:0.5 to about 1:2 (volume:volume), but is not limited thereto.

The ink composition including the semiconductor nanoparticle may exhibit a viscosity required in an inkjet printing process. A viscosity may range from about 0.5 centipoise (cPs) to about 30 cPs, about 1 cPs to about 15 cPs, about 1.5 cPs to about 10 cPs, about 2 cPs to about 8 cPs, about 2.5 cPs to about 5 cPs, about 2.8 cPs to about 3.5 cPs, or a combination thereof.

The composition for inkjet printing process may exhibit surface tension or wettability with respect to a common layer, for example, a hole auxiliary layer or an electron auxiliary layer. The surface tension may range from about 10 millinewton per meter (mN/m) to about 100 mN/m, about 15 mN/m to about 80 mN/m, about 20 mN/m to about 50 mN/m, about 25 mN/m to about 45 mN/m, about 30 mN/m to about 40 mN/m, about 33 mN/m to about 38 mN/m, or a combination thereof.

Forming a light emitting layer by inkjet printing may include placing an ink composition including the semiconductor nanoparticle in a device equipped with an inkjet printing nozzle, and ejecting/depositing a droplet of the composition from the nozzle toward a desired location (e.g., a pixel defining layer (PDL) or a hole transport layer or electron transport layer surface defined by a partition wall or bank). (Refer to FIG. 4 and FIG. 5)

In the electroluminescent device of an embodiment, a thickness of the light emitting layer can be appropriately selected. In an embodiment, the light emitting layer may include a monolayer(s) of semiconductor nanoparticles. In another embodiment, the light emitting layer may include one or more monolayers of semiconductor nanoparticles, for example, two or more layers, three or more layers, or four or more layers, and 20 layers or less, 10 layers or less, 9 layers or less, 8 layers or less, 7 layers or less, or 6 layers or less. The light emitting layer may have a thickness of greater than or equal to about 5 nm, for example, greater than or equal to about 10 nm, greater than or equal to about 20 nm, or greater than or equal to about 30 nm and less than or equal to about 200 nm, for example, less than or equal to about 150 nm, less than or equal to about 100 nm, less than or equal to about 90 nm, less than or equal to about 80 nm, less than or equal to about 70 nm, less than or equal to about 60 nm, or less than or equal to about 50 nm. The light emitting layer may have a thickness of, for example about 10 nm to about 150 nm, for example about 20 nm to about 100 nm, for example about 30 nm to about 50 nm.

The forming a light emitting layer 3 including the semiconductor nanoparticle may be performed by obtaining a composition including the semiconductor nanoparticle and an organic solvent and applying or depositing it on a substrate or a charge auxiliary layer by an appropriate method (e.g., by spin coating, inkjet printing, or the like). The forming of the light emitting layer may further include heat-treating the applied or deposited semiconductor nanoparticle layer. The heat-treating temperature is not particularly limited and may be appropriately selected considering the boiling point of the organic solvent, or the like. For example, the heat-treating temperature may be greater than or equal to about 60° C., for example, greater than or equal to about 70° C. and less than or equal to about 250° C., or less than or equal to about 180° C. The type of the organic solvent is not particularly limited and may be appropriately selected. In an embodiment, the organic solvent may include a (substituted or unsubstituted) aliphatic hydrocarbon organic solvent, a (substituted or unsubstituted) aromatic hydrocarbon organic solvent, an acetate solvent, or a combination thereof.

The light emitting layer may have a single layer or a multilayer structure in which two or more layers are stacked. Adjacent layers in a multilayer structure (e.g., the first emitting layer and the second emitting layer) may be configured to emit the light of the same color (green light, blue light, or red light). In a multilayer structure, adjacent layers (e.g., a first light emitting layer and a second light emitting layer) may have the same or different compositions and/or ligands from each other. In an embodiment, the light emitting layer or the multilayer light emitting layer including two or more layers may have a halogen content that changes (increases or decreases) in a thickness direction. In the (multilayer) light emitting layer according to an embodiment, the halogen content may increase towards the electron auxiliary layer. In the (multilayer) light emitting layer according to an embodiment, the organic ligand content may decrease towards the electron auxiliary layer. In the light emitting layer according to an embodiment, the halogen content may decrease toward the electron auxiliary layer. In the (multilayer) light emitting layer according to an embodiment, the organic ligand content may increase towards the electron auxiliary layer.

The electroluminescent device may include a charge (hole or electron) auxiliary layer between the first electrode and the second electrode (e.g., the first electrode 10 and the second electrode 50). For example, the electroluminescent display device may include a hole auxiliary layer (HTL) 20 or an electron auxiliary layer (ETL) 40 between the first electrode 10 and the light emitting layer 30 and/or between the second electrode 50 and the light emitting layer 30 (Refer to FIGS. 2 and 3).

The light emitting device according to an embodiment may further include a hole auxiliary layer. The hole auxiliary layer 20 is located between the first electrode 10 and the light emitting layer 30. The hole auxiliary layer 20 may include a hole injection layer, a hole transport layer, and/or an electron (or hole) blocking layer. The hole auxiliary layer 20 may be a layer of a single component or a multilayer structure in which adjacent layers include different components.

The hole auxiliary layer 20 may have a HOMO energy level that can be matched with the HOMO energy level of the light emitting layer 30 (e.g., 30R, 30G, or 30B) in order to enhance mobility of holes transferred from the hole auxiliary layer 20 to the light emitting layer 13. In an embodiment, the hole auxiliary layer 20 may include a hole injection layer close to the first electrode 10 and a hole transport layer close to the light emitting layer 30.

The material included in the hole auxiliary layer 20 (e.g., a hole transport layer, a hole injection layer, or an electron blocking layer) is not particularly limited, and may include at least one of, for example, poly(9,9-dioctyl-fluorene-co-N-(4)-butylphenyl)-diphenylamine) (TFB), polyarylamine, poly(N-vinylcarbazole), poly(3,4-ethylenedioxythiophene) (PEDOT), poly(3,4-ethylenedioxythiophene) polystyrene sulfonate (PEDOT:PSS), polyaniline, polypyrrole, N,N,N′,N′-tetrakis(4-methoxyphenyl)-benzidine (TPD), 4,4′-bis[N-(1-naphthyl)-N-phenyl-amino]biphenyl(α-NPD), m-MTDATA (4,4′,4″-Tris[phenyl(m-tolyl)amino]triphenylamine), 4,4′,4″-tris(N-carbazolyl)-triphenylamine (TCTA), 1,1-bis[(di-4-toylamino)phenylcyclohexane (TAPC), a p-type metal oxide (e.g., NiO, WO₃, MoO₃, or the like), a carbon-containing material such as graphene oxide, or a combination thereof, but is not limited thereto.

In the hole auxiliary layer(s), the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, for example, less than or equal to about 40 nm, less than or equal to about 35 nm, or less than or equal to about 30 nm, but is not limited thereto.

The electronic auxiliary layer 40 is located between the light emitting layer 30 and the second electrode 50. The electron auxiliary layer 40 may include, for example, an electron injection layer, an electron transport layer, and/or a hole (or electron) blocking layer. The electron auxiliary layer may include for example an electron injection layer (EIL) to facilitate electron injection, an electron transport layer (ETL) to facilitate electron transport, a hole blocking layer (HBL) to inhibit hole transport, or a combination thereof.

In an embodiment, the electron injection layer may be disposed between the electron transport layer and the second electrode. For example, the hole blocking layer may be disposed between the emission layer and the electron transport (injection) layer, but is not limited thereto. A thickness of each layer may be appropriately selected. For example, a thickness of each layer may be greater than or equal to about 1 nm and less than or equal to about 500 nm, but is not limited thereto. The electron injection layer may be an organic layer formed by deposition. The electron transport layer may include an inorganic oxide nanoparticle or may be an organic layer formed by deposition.

The electron transport layer (ETL), electron injection layer (EIL), and/or hole blocking layer may include, for example 1,4,5,8-naphthalene-tetracarboxylic dianhydride (NTCDA), bathocuproine (BCP), tris[3-(3-pyridyl)-mesityl]borane (3TPYMB), LiF, tris(8-hydroxyquinoline)aluminum (Alq₃), tris(8-hydroxyquinoline) gallium (Gaq₃), tris-(8-hydroxyquinoline) indium (Inq₃), bis(8-hydroxyquinoline) zinc (Znq₂), bis(2-(2-hydroxyphenyl)benzothiazolate) zinc (Zn(BTZ)₂), bis(10-hydroxybenzo[h]quinolinato) beryllium (BeBq₂), 8-(4-(4,6-di(naphthalen-2-yl)-1,3,5-triazin-2-yl)phenyl) quinolone (ET204), 8-hydroxyquinolinato lithium (Liq), n-type metal oxide (e.g., ZnO, HfO₂, or the like), and a combination thereof, but is not limited thereto.

The electron auxiliary layer 40 may include an electron transport layer. The electron transport layer may include a plurality of nanoparticles. The plurality of nanoparticles may include a metal oxide including zinc.

The metal oxide may include zinc oxide, zinc magnesium oxide, or a combination thereof. The metal oxide may include Zn₁₋ₓMₓO (wherein, M is Mg, Ca, Zr, W, Li, Ti, Y, Al, or a combination thereof and 0≤x≤0.5). In an embodiment, M in Zn₁₋ₓMₓO may be magnesium (Mg). In an embodiment, x in Zn₁₋ₓMₓO may be greater than or equal to about 0.01 and less than or equal to about 0.3, for example, less than or equal to about 0.25, less than or equal to about 0.2, or less than or equal to about 0.15.

The absolute value of the LUMO of the aforementioned nanoparticles included in the emitting layer may be greater or smaller than the absolute value of the LUMO of the metal oxide. The average size of the nanoparticle may be greater than or equal to about 1 nm, for example, greater than or equal to about 1.5 nm, greater than or equal to about 2 nm, greater than or equal to about 2.5 nm, or greater than or equal to about 3 nm and less than or equal to about 10 nm, less than or equal to about 9 nm, less than or equal to about 8 nm, less than or equal to about 7 nm, less than or equal to about 6 nm, or less than or equal to about 5 nm.

In an embodiment, the thickness of each of the electron auxiliary layers 40 (e.g., electron injection layer, electron transport layer, or hole blocking layer) may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm, but is not limited thereto.

A device according to an embodiment may have a normal structure. In an embodiment, in the device, the first electrode 10 disposed on the transparent substrate 100 may include a metal oxide-containing transparent electrode (e.g., an indium tin oxide (ITO) electrode), and the second electrode (cathode) 50 facing the first electrode 10 may include a conductive metal (e.g., having a relatively low work function, Mg, Al, or the like). The hole auxiliary layer 20 (e.g., a hole injection layer such as poly(3,4-ethylenedioxythiophene) polystyrene sulfonate (PEDOT:PSS) and/or p-type metal oxide and/or a hole transport layer such as 2-(trifluoromethyl)benzimidazole (TFB) and/or polyvinylcarbazole (PVK) may be provided between the first electrode 10 and the light emitting layer 30. The hole injection layer may be disposed close to the transparent electrode and the hole transport layer may be disposed close to the light emitting layer. The electron auxiliary layer 40 such as an electron injection/transport layer may be disposed between the light emitting layer 30 and the second electrode 50. (Refer to FIG. 2)

A device according to another embodiment may have an inverted structure. As used herein, the second electrode 50 disposed on the transparent substrate 100 may include a metal oxide-containing transparent electrode (e.g., ITO), and the first electrode 10 facing the second electrode 50 may include a metal (e.g., having a relatively high work function, Au, Ag, or the like). For example, an (optionally doped) n-type metal oxide (crystalline Zn metal oxide) or the like may be disposed as an electron auxiliary layer 40 (e.g., an electron transport layer) between the transparent electrode 50 and the light emitting layer 30. MoO₃ or other p-type metal oxide may be disposed as a hole auxiliary layer 20 (e.g., a hole transport layer including TFB and/or PVK and/or a hole injection layer including MoO₃ or other p-type metal oxide) between the metal first electrode 10 and the light emitting layer 30. (Refer to FIG. 3)

The aforementioned device may be manufactured by an appropriate method. For example, the electroluminescent device may be manufactured by optionally forming a hole auxiliary layer (e.g., by deposition or coating) on a substrate on which an electrode, forming a light emitting layer including nanoparticles (e.g., a pattern of the aforementioned semiconductor nanoparticles), and forming (optionally, an electron auxiliary layer and) an electrode (e.g., by vapor deposition or coating) on the light emitting layer. A method of forming the electrode/hole auxiliary layer/electron auxiliary layer may be appropriately selected and is not particularly limited. In an embodiment, each layer included in the hole transport region, each layer included in the light emitting layer, and each layer included in the electron transport region may be formed in a predetermined region using various methods, such as a vacuum deposition method, a spin coating method, a casting method, a Langmuir-Blodgett (LB) method, an inkjet printing method, a laser printing method, a laser induced thermal imaging (LITI) method, or the like For example, the light emitting layer may be formed by an inkjet printing method. The inkjet process is as described herein.

When each layer included in the hole transport region, the light emitting layer, and each layer included in the electron transport region are formed by a vacuum deposition method, the deposition condition may be appropriately selected. For example, a deposition temperature may be about 100° C. to about 500° C., a vacuum degree may be about 10-8 to about 10-3 torr, a deposition rate may be in the range of about 0.01 to about 100 angstrom/sec. The deposition condition may be selected by considering the material to be included in the layer to be formed and the structure of the layer to be formed.

The electroluminescent device may be configured to emit blue light. A wavelength range of the blue light is as described above. The electroluminescent device may be configured to emit green light. A wavelength range of green light is as described above. The electroluminescent device may be configured to emit red light. A wavelength range of red light is as described above.

The electroluminescent device may have a maximum external quantum efficiency of greater than or equal to about 4%, greater than or equal to about 5%, greater than or equal to about 5.3%, greater than or equal to about 5.4%, greater than or equal to about 6%, greater than or equal to about 7%, greater than or equal to about 8%, greater than or equal to about 9%, greater than or equal to about 10%, greater than or equal to about 10.5%, greater than or equal to about 11%, greater than or equal to about 11.5%, greater than or equal to about 12%, greater than or equal to about 12.5%, greater than or equal to about 13%, greater than or equal to about 13.5%, or greater than or equal to about 14%. The electroluminescent device may have a maximum external quantum efficiency of less than or equal to about 50%, less than or equal to about 40%, less than or equal to about 30%, or less than or equal to about 20%.

The electroluminescent device may have a maximum luminance of 40,000 nit (cd/m²), greater than or equal to about 50,000 nit, greater than or equal to about 60,000 nit, greater than or equal to about 70,000 nit, greater than or equal to about 80,000 nit, greater than or equal to about 90,000 nit, greater than or equal to about 95,000 nit, greater than or equal to about 100,000 nit, greater than or equal to about 105,000 nit, greater than or equal to about 110,000 nit, greater than or equal to about 115,000 nit, greater than or equal to about 120,000 nit, greater than or equal to about 125,000 nit. The maximum luminance may be about 3000 nit to about 500,000 nit.

The electroluminescent device can exhibit improved life-span. In an embodiment, the life-span of the electroluminescent device can be measured while driving at a predetermined initial luminance (e.g., about 146 nit or about 650 nit).

The life-span T50 of the electroluminescent device may be greater than or equal to about 10 hours, greater than or equal to about 50 hours, greater than or equal to about 80 hours, greater than or equal to about 100 hours, greater than or equal to about 120 hours, greater than or equal to about 130 hours, greater than or equal to about 150 hours, greater than or equal to about 160 hours, greater than or equal to about 200 hours, greater than or equal to about 250 hours, greater than or equal to about 260 hours, greater than or equal to about 270 hours, greater than or equal to about 300 hours, greater than or equal to about 308 hours, greater than or equal to about 310 hours, greater than or equal to about 320 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1000 hours, greater than or equal to about 1500 hours or more.

The life-span T90 of the electroluminescent device may be greater than or equal to about 10 hours, greater than or equal to about 15 hours, greater than or equal to about 20 hours, greater than or equal to about 25 hours, greater than or equal to about 30 hours, greater than or equal to about 33 hours, greater than or equal to about 35 hours, greater than or equal to about 40 hours, greater than or equal to about 45 hours, greater than or equal to about 50 hours, greater than or equal to about 75 hours, greater than or equal to about 100 hours, greater than or equal to about 125 hours, greater than or equal to about 150 hours, greater than or equal to about 175 hours, greater than or equal to about 180 hours, greater than or equal to about 200 hours, greater than or equal to about 210 hours, greater than or equal to about 300 hours, greater than or equal to about 310 hours, greater than or equal to about 350 hours, greater than or equal to about 380 hours, greater than or equal to about 400 hours, greater than or equal to about 450 hours, greater than or equal to about 500 hours, greater than or equal to about 600 hours, greater than or equal to about 700 hours, greater than or equal to about 800 hours, greater than or equal to about 900 hours, greater than or equal to about 1000 hours, greater than or equal to about 1500 hours, or more.

In an embodiment, T50 may be about 150 hours to about 5000 hours, about 400 hours to about 4000 hours, about 500 hours to about 3500 hours, about 750 hours to about 2000 hours, about 1000 hours to about 1500 hours, or a combination thereof.

In an embodiment, T90 may be in a range of about 13 hours to about 5000 hours, about 15 hours to about 2800 hours, about 18 hours to about 1200 hours, about 22 hours to about 1000 hours, about 31 hours to about 800 hours, about 50 hours to about 700 hours, about 60 hours to about 500 hours, about 80 hours to about 400 hours, or a combination thereof.

Another embodiment relates to a display device (e.g., a display panel) including an electroluminescent device according to an embodiment.

The display device (e.g., a display panel) may include a first pixel and a second pixel configured to emit light of a different color from the first pixel. In an embodiment, the first light from the light emitting layer may be extracted (e.g., in the Z direction) through the second electrode (Refer to FIG. 4 or FIG. 5). In an embodiment, the first light may be extracted through the (transparent) first electrode and optionally the substrate 100 (Refer to FIG. 3). The light emitting layer may be arranged within a pixel (or subpixel) in a display device (display panel) described later. (Refer to FIG. 4 or FIG. 5)

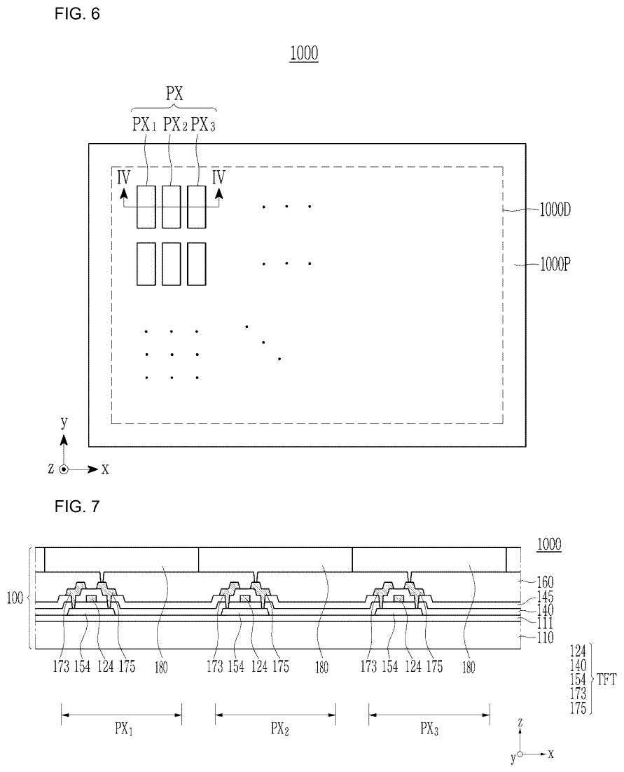

Referring to FIG. 6, a display panel 1000 according to an embodiment may include a display area 1000D for displaying an image and, optionally, a non-display area 1000P located around the display area 1000D and having a bonding material disposed thereon.

The display area 1000D may include a plurality of pixels PX arranged along rows (e.g., in the x direction) and/or columns (e.g., in the y direction), and each pixel PX may include a plurality of subpixels PX₁, PX₂, and PX₃ that display different colors. Here, as an example, a configuration in which three subpixels PX₁, PX₂, and PX₃ form one pixel is illustrated, but the present disclosure is not limited thereto and may further include additional subpixels such as a white subpixel, or may further include one or more subpixels displaying the same color. The plurality of subpixels PXs may be arranged in, for example, a Bayer matrix, a PenTile matrix, and/or a diamond matrix, but is not limited thereto.

Each subpixel PX₁, PX₂, and PX₃ may display a color of three primary colors or a combination of three primary colors, for example, red, green, blue, or a combination thereof. For example, a first subpixel PX₁ may display red, a second subpixel PX₂ may display green, and a third subpixel PX₃ may display blue.

Although the drawing illustrates an example in which all subpixels have the same size, the present disclosure is not limited thereto, and at least one of the subpixels may be larger or smaller than the other subpixels. Although the drawing illustrates an example in which all subpixels have the same shape, the present disclosure is not limited thereto, and at least one of the subpixels may have a different shape from the other subpixels.

In an embodiment, the display panel may include a light emitting panel 100 (refer to FIG. 7) including a substrate 110, a buffer layer 111, a thin film transistor TFT, and a light emitting device 180. The display panel may include circuit elements for switching and/or driving each light emitting device.

Referring to FIG. 7, in the light emitting panel, light emitting devices 180 may be arranged in each subpixel PX₁, PX₂, and PX₃, and the light emitting devices 180 arranged in the subpixels PX₁, PX₂, and PX₃ may be driven independently. The subpixel may include a blue pixel, a red pixel, or a green pixel. At least one of the light emitting devices 180 may be an electroluminescent device according to an embodiment.

The substrate 110 is as described above. The buffer layer 111 may include an organic, inorganic, or organic-inorganic material, and may include, for example, an oxide, a nitride or an oxynitride, and may include, for example, silicon oxide, silicon nitride, silicon oxynitride or a combination thereof, but is not limited thereto. The buffer layer 111 may have one layer or two or more layers and may cover the entire surface of the substrate 110. The buffer layer 111 may be omitted.

The thin film transistor TFT may be a three-terminal device for switching and/or driving a light emitting device 180, and one or more thin film transistors TFT may be included for each subpixel. The thin film transistor TFT includes a gate electrode 124, a semiconductor layer 154 overlapped with the gate electrode 124, a gate insulating film 140 between the gate electrode 124 and the semiconductor layer 154, and a source electrode 173 and a drain electrode 175 electrically connected to the semiconductor layer 154. The drawing shows a coplanar top gate structure as an example, but is not limited thereto and the thin film transistor TFT may have various structures.

The gate electrode 124 is electrically connected to a gate line (not shown) and may include a low-resistance metal such as aluminum (Al), molybdenum (Mo), copper (Cu), titanium (Ti), silver (Ag), gold (Au), alloys thereof, or a combination thereof, but is not limited thereto.

The semiconductor layer 154 may be an inorganic semiconductor such as amorphous silicon, polycrystalline silicon, an oxide semiconductor; an organic semiconductor; an organic-inorganic semiconductor; or a combination thereof. For example, the semiconductor layer 154 may include an oxide semiconductor including at least one of indium (In), zinc (Zn), tin (Sn), and gallium (Ga), and the oxide semiconductor may include, for example, indium-gallium-zinc oxide, zinc-tin oxide, or a combination thereof, but is not limited thereto. The semiconductor layer 154 may include a channel region and a doped region disposed on both sides of the channel region and electrically connected to the source electrode 173 and the drain electrode 175, respectively.

The gate insulating film 140 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The drawing shows an example in which the gate insulating film 140 is formed on the entire surface of the substrate 110, but is not limited thereto and the gate insulating film 140 may be selectively formed between the gate electrode 124 and the semiconductor layer 154. The gate insulating film 140 may have one layer or two or more layers.

The source electrode 173 and the drain electrode 175 may include a low-resistance metal such as aluminum (Al), molybdenum (Mo), copper (Cu), titanium (Ti), silver (Ag), gold (Au), alloys thereof, or a combination thereof, but is not limited thereto. The source electrode 173 and the drain electrode 175 may each be electrically connected to the doping region of the semiconductor layer 154. The source electrode 173 is electrically connected to a data line (not shown), and the drain electrode 175 is electrically connected to a light emitting device 180 described later.

An interlayer insulating film 145 is additionally formed between the gate electrode 124 and the source/drain electrodes 173 and 175. The interlayer insulating film 145 may include an organic, inorganic, or organic-inorganic material, and may include, for example, an oxide, a nitride or an oxynitride, and may include, for example, silicon oxide, silicon nitride, silicon oxynitride, or a combination thereof, but is not limited thereto. The interlayer insulating film 145 may have one layer or two or more layers.

In an embodiment, a protective film 160 may be formed on a thin film transistor TFT. The protective film 160 may be, for example, a passivation film, but is not limited thereto. The protective film 160 may include an organic, inorganic, or organic-inorganic material, and may include polyacrylic acid, polyimide, polyamide, polyamideimide or a combination thereof, but is not limited thereto. The protective film 160 may have one or more layers.

In an embodiment, one of the first electrodes 1 and 10 and the second electrodes 5 and 50 may be a pixel electrode connected to the TFT and the other may be a common electrode.

The electroluminescent device of an embodiment or the display device including the same may be used in a top emission manner, a bottom emission manner, a double-sided emission manner, or a combination thereof.

In an embodiment, the first electrode 10 may be a light transmitting electrode and the second electrode 50 may be a reflective electrode, and the display panel may be a bottom emission type display panel that emits light toward the first electrode 10 and, if present, the substrate 110. In an embodiment, the first electrode 10 may be a reflective electrode and the second electrode 50 may be a light transmitting electrode, and the display panel may be a top emission type display panel that emits light opposite the first electrode 10 and, if present, the substrate 100. In an embodiment, both the first electrode and the second electrode may be light transmitting electrodes, and the display panel 1000 may be a both side emission type display panel that emits light to the substrate 110 side and the opposite side of the substrate 110.

The display device may include a VR/AR device, a portable terminal device, a monitor, a laptop, a television, an electronic board, a camera, or an electrical component (for example, for an automobile).

Hereinafter, specific examples are illustrated. However, these examples are exemplary, and the present disclosure is not limited thereto.

### EXAMPLES

### Analysis Methods

### [1] Photoluminescence Analysis

Photoluminescence analysis was performed using a Hitachi F-7000 photospectrometer.

### [2] ICP Analysis

Inductively coupled plasma atomic emission spectroscopy (ICP-AES) analysis was performed using a Shimadzu ICPS-8100.

### [3] SIMS Analysis

SIMS analysis was performed using a Hybrid-SIMS instrument (IONTOF, model M₆).

### [4] Electroluminescent Property Analysis and Life-Span Measurement

When applying voltage, the current according to the voltage was measured using a Keithley 2635B source meter, and the EL luminescence luminance was measured using a CS2000 spectrometer.

T50(h): when driving with predetermined luminance (e.g., 650 nit or 146 nit), time (hr) taken for the luminance to reach 50% based on 100% of the initial luminance was measured.

The following synthesis was performed under an inert gas atmosphere (under a nitrogen flowing condition), unless otherwise specified. A precursor content was a molar content, unless otherwise specified.

### Reference Example 1: Production of Particle Including First Semiconductor Nanocrystal and Second Semiconductor Nanocrystal

Selenium (Se), sulfur(S), and tellurium (Te) were dispersed in trioctylphosphine (TOP) to obtain 2 molar (M) Se/TOP stock solution, 1 M S/TOP stock solution, and 0.1 M Te/TOP stock solution.

4.5 millimoles (mmol) of zinc acetate was added with oleic acid to a 300 milliliters (mL) reaction flask containing trioctylamine and then, heated to 120° C. under vacuum, and after 1 hour, an atmosphere inside the reactor was converted to an inert gas.

After heating the flask to 240° C. to 300° C., the prepared Se/TOP and Te/TOP stock solutions were rapidly injected thereinto at a Te/Se ratio=1/15. A reaction proceeded for 40 minutes. When the reaction was completed, after rapidly cooling the reaction solution to room temperature, ethanol was added thereto and then, centrifuged to obtain ZnTeSe semiconductor nanocrystals. The obtained precipitates were dispersed in hexane to obtain ZnSeTe cores. The cores had an average size of about 3 nm.

Zinc acetate was added with oleic acid to a 300 mL reaction flask containing TOA and then, vacuum-treated at 120° C. The flask was internally substituted with nitrogen (N₂). The reaction flask was heated to a reaction temperature of 340° C. After rapidly adding the hexane dispersion of the ZnSeTe cores to the reaction flask, the Se/TOP stock solution was subsequently added thereto to proceed with a reaction. To form a ZnSe shell, the selenium precursor was used in an amount of 0.67 mole per 1 mole of the zinc precursor.

When the reaction was completed, after cooling the reactor to room temperature, ethanol was added to the reaction solution to precipitate a nanoparticle including first semiconductor nanocrystals (ZnTeSe) and second semiconductor nanocrystals (ZnSe). The precipitates, which were recovered through centrifugation, were confirmed to be able to be dispersed in a hydrocarbon solvent such as octane and the like.

### Reference Example 2: Synthesis of ZnMgO Nanoparticle

Zinc acetate dihydrate and magnesium acetate tetrahydrate were added to a reactor containing dimethylsulfoxide and then, heated to 60° C. in the air. Subsequently, an ethanol solution of tetramethylammonium hydroxide pentahydrate was added to the reactor. After stirring the mixture for 1 hour, precipitates were centrifuged and then, dispersed in ethanol to obtain a Zn₁₋ₓMgₓO nanoparticle (x=0.15).

The obtained nanoparticles were subjected to transmission electron microscope analysis. As a result, the nanoparticles were confirmed to have an average size of about 3 nm.

### Preparation Example 1-1

Zinc acetate and oleic acid were respectively added to trioctylamine and then, heated at 120° C. for 1 hour under vacuum to prepare a zinc precursor. A sulfur precursor was prepared by adding trimethyl aluminum to a trioctylphosphine solution of dodecanethiol at room temperature. It was confirmed that a reaction between the dodecanethiol and the trimethylaluminum generated heat.

After adding trioctylamine to a 300 mL reaction flask, the flask was heated to 120° C. for 1 hour under vacuum and then, internally substituted with nitrogen (N₂). While the flask was heated to a reaction temperature of 340° C., after adding an octane dispersion of the particle prepared in the reference example 1, the zinc precursor and the sulfur precursor were respectively divided into two parts and thus, twice injected thereinto to proceed with a reaction. The reaction was carried out for about 70 minutes in total.

The zinc acetate, dodecanethiol, and trimethylaluminum were respectively used in an amount of 2.1 mmol, 1.6 mmol, and 0.6 mmol.

After cooling the reactor to room temperature, ethanol was added to the reaction solution to promote precipitation of semiconductor nanoparticles, which were recovered through centrifugation and then, dispersed in octane.

The produced semiconductor nanoparticle was subjected to inductively coupled plasma atomic emission spectrometry (ICP-AES) analysis, and the results were summarized in Table 2.

### Preparation Example 1-2

A semiconductor nanoparticle was produced in the same manner as in Preparation Example 1-1 except that 0.4 mmol of trimethylaluminum was used. The semiconductor nanoparticles were dispersed in octane.

### Preparation Example 2

A semiconductor nanoparticle was produced in the same manner as in Preparation Example 1-1 except that 2 mmol of trimethylgallium instead of the trimethylaluminum was used. The obtained semiconductor nanoparticle was dispersed in octane. The produced particle was subjected to ICP-AES analysis, and the results were summarized in Table 2.

### Preparation Example 3

A semiconductor nanoparticle was produced in the same manner as in Preparation Example 1-1 except that zirconium (IV) ethoxide was used instead of the trimethylaluminum. The obtained semiconductor nanoparticle was dispersed in octane. The produced particle was subjected to ICP-AES analysis, and the results were summarized in Table 2.

### Preparation Example 4

A semiconductor nanoparticle was produced in the same manner as in Preparation Example 1-1 except that diethylmagnesium was used instead of the trimethylaluminum. The obtained semiconductor nanoparticle was dispersed in octane. The produced particle was subjected to ICP-AES analysis, and the results were summarized in Table 2.

### Preparation Example 5

A semiconductor nanoparticle was produced in the same manner as in Preparation Example 1-1 except that 1.12 mol of triethylaluminum was used instead of the trimethylaluminum. The obtained semiconductor nanoparticle was dispersed in octane.

### Comparative Preparation Example 1

A semiconductor nanoparticle was produced in the same manner as in Preparation Example 1-1 except that dodecanethiol was used as the sulfur precursor without a metal dopant compound. The obtained semiconductor nanoparticle was dispersed in octane. As a result of the ICP analysis, it was confirmed that there was no aluminum component.

### Comparative Preparation Example 2

A semiconductor nanoparticle was produced in the same manner as in Preparation Example 1-1 except that the reaction temperature was changed to 240° C., and aluminum isopropoxide was used as the metal dopant compound. The obtained semiconductor nanoparticle was dispersed in octane.

TABLE 2

| Preparation Example | | | Zn/(Se + | S/(Se + | | | |
|---|---|---|---|---|---|---|---|
| Content of metal dopant (M) | Te/Se | S/Se | S + Te) | Te) | Zn/M | M/S | M/Te |
| Preparation Example 1-1 | 0.007 | 0.667 | 1.14 | 0.66 | 265.5 | 0.011 | 1 |
| aluminum 0.6 mmol | | | | | | | |
| Preparation Example 2 | 0.007 | 0.617 | 1,04 | 0.62 | 18.9 | 0.145 | 13 |
| gallium 0.2 mmol | | | | | | | |
| Preparation Example 3 | 0.003 | 0.587 | 1.11 | 0.59 | 32.4 | 0.09 | 16 |
| zirconium 0.2 mmol | | | | | | | |
| Preparation Example 4 | 0.003 | 0.527 | 1.120 | 0.525 | 19.769 | 0.165 | 26 |
| magnesium 0.2 mmol | | | | | | | |

M: metal dopant (aluminum, gallium, zirconium, or magnesium)

Referring to the results of Table 2, the semiconductor nanoparticles according to the embodiments were confirmed to include the metal dopants.

### Experimental Example 1: SIMS Analysis

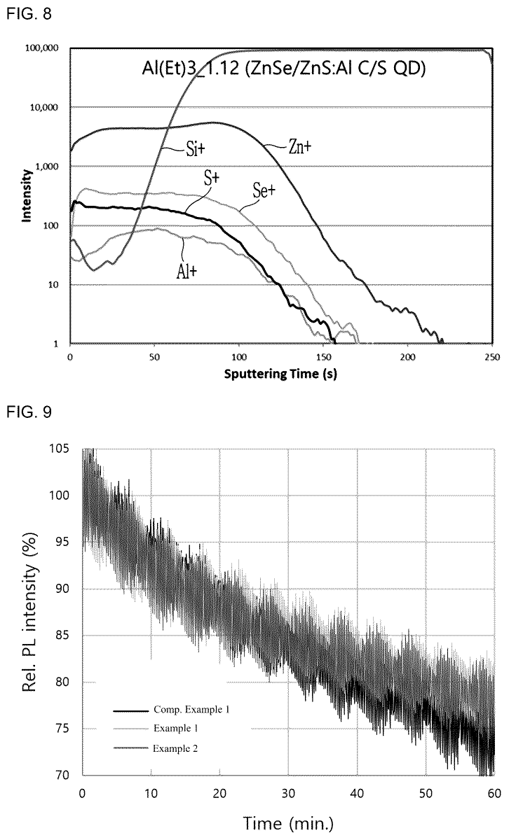

The octane dispersion of the semiconductor nanoparticle of Preparation Example 5 was spin-coated on a silicon substrate to form a thin film (a thickness: 30 nm). The obtained thin film was subjected to secondary ion mass spectrometry analysis, and the results are shown in FIG. 8. Referring to the results of FIG. 8, it was confirmed that a metal dopant with the components (zinc, selenium, sulfur) of the semiconductor nanoparticle was detected from the obtained thin film.

As a result, it was confirmed that sulfur had intensity of about 250, Al had intensity of 90, and an intensity ratio of the aluminum to the sulfur was 0.36 at middle sputtering time 50 s, the time can be considered as an average thickness of the film. A ratio of a depth profile area of the aluminum to that of the sulfur was confirmed to be greater than or equal to about 0.1.

### Experimental Example 2: Evaluation of Light Stability Under UV Irradiation

The synthesized semiconductor nanoparticles according to Preparation Example 1-2 and 5 and Comparative Preparation Example 1 were respectively dispersed in hexane and then, diluted to prepare specimens. The specimens were measured with respect to photoluminescence intensity of the semiconductor nanoparticle every 10 seconds, while continuously irradiating UV light (a wavelength-372 nm) by using a PL spectrophotometer, and the results are shown in FIG. 9.

Referring to the results of FIG. 9, the semiconductor nanoparticle dispersions having an Al-doped ZnS shell layer according to the embodiments exhibited improved photostability, as operated in a photoluminescent manner by the irradiation of UV light (a wavelength of −372 nm).

### DEVICE EXAMPLES

### Example 1

Using the semiconductor nanoparticle (including an aluminum dopant) manufactured in Preparation Example 1-1, a light emitting device having a structure of ITO/PEDOT:PSS (300 angstroms)/TFB (250 angstroms)/semiconductor nanoparticle emitting layer (350 angstroms)/ZnMgO (200 angstroms)/Al was manufactured in the following manner:

PEDOT:PSS and TFB (or PVK) layers were formed as a hole injection layer and a hole transport layer by spin coating on a glass substrate on which an ITO electrode (first electrode) was deposited. A light emitting layer was formed by spin-coating the semiconductor nanoparticle solution prepared in Preparation Example 1-1 on the formed TFB layer (25 nm). On the light emitting layer, the ethanol dispersion of the zinc magnesium oxide nanoparticle of Reference Example 2 was coated to form an electron auxiliary layer, and on the electron auxiliary layer, an Al electrode was formed through deposition to manufacture a light emitting device.

The electroluminescent property and life-span of the manufactured devices were measured, and the results are summarized in Table 3.

### Example 2

An electroluminescent device was manufactured in the same manner as in Example 1 except that the semiconductor nanoparticle (containing a gallium dopant) of Preparation Example 2 was used. The manufactured device was measured with respect to an electroluminescent property and a life-span. The results were summarized in Table 3.

### Example 3

An electroluminescent device was manufactured in the same manner as in Example 1, except that the semiconductor nanoparticle (containing a zirconium dopant) produced in Preparation Example 3 were used. The device was measured with respect to an electroluminescent property and a life-span, and the result was summarized in Table 3.

### Comparative Example 1

An electroluminescent device was manufactured in the same manner as in Example 1, except that the semiconductor nanoparticle produced in Comparative Preparation Example 1 were used. The device was measured with respect to an electroluminescent property and a life-span, and the result was summarized in Table 3.

### Comparative Example 2

An electroluminescent device was manufactured in the same manner as in Example 1, except that the semiconductor nanoparticle produced in Comparative Preparation Example 3 were used. The device was measured with respect to an electroluminescent property and a life-span, and the result was summarized in Table 3.

TABLE 3

| | Relative | Relative |
|---|---|---|
| | maximum luminance | T50 |
| Example 1 | 112% | 127% |
| Example 2 | 107% | 105% |
| Example 3 | 105% | 116% |
| Example 4 | 102% | 194% |
| Comparative Example 1 | 100% | 100% |
| Comparative Example 2 | 8.4% | 0.2% |

$$Relative maximum luminance ( \% ) : [ Maximum luminance of the given device / Maximum luminance of the device in Comparative Example 1 ] \times 100$$

$$Relative T 50 ( \% ) : [ T 50 hours of the given device / T 50 hours of the device in Comparative Example 1 ] \times 100$$

Referring to the results of Table 3, the devices of the examples, compared with that of Comparative Example 1, exhibited an improved EL property and an increase in life-span. In addition, referring to the results of Table 3, the device of Comparative Example 2, compared with that of Comparative Example 1, exhibited a sharply deteriorated electroluminescent property and also, rapidly reduced life-span.

### Experimental Example 3: Manufacturing of EOD (Electron Only Device) and Evaluation of Electron Transport Ability

The semiconductor nanoparticles according to Preparation Examples 1-1, 2, and 4 and Comparative Preparation Example 1 were respectively used to manufacture a light emitting device with a structure of ITO/ZnMgO (200 angstrom)/semiconductor nanoparticle light emitting layer (280 angstrom)/ZnMgO (200 angstrom)/Al (a device structure that electrons alone were allowed to flow, as holes injection were suppressed from ITO by ZMO) in the following method: On a glass substrate deposited with an ITO electrode (first electrode), a zinc magnesium oxide nanoparticle layer was formed as an electron transport layer (ETL), and on the electron transport layer (ETL), a semiconductor nanoparticle solution prepared in Preparation Example 1-2 was spin-coated to form a light emitting layer. On the light emitting layer, another zinc magnesium oxide nanoparticle was formed, and then, an Al electrode was deposited, manufacturing an electron-only device (EOD 1, EOD 2, EOD 3, EOD 4).

The device was measured with respect to current density (milliampere per square centimeter (mA/cm²)) by increasing (forward scan) and decreasing (backward scan) a voltage within a range of 0 to 8 V between ITO electrode and Al electrode, and the results were shown in Table 4.

TABLE 4

| | | Current density |
|---|---|---|
| | Semiconductor nanoparticle | at 5 volts |
| | included in light | J at 5 V, |
| | emitting layer | 3^{rd} (mA/cm²) |
| EOD 1 | Preparation | 21.61 |
| | Example 1-1 (Al) | |
| EOD 2 | Preparation | 5.67 |
| | Example 2 (Ga) | |
| EOD 3 | Preparation | 15.35 |
| | Example 4 (Mg) | |
| EOD 4 | Comparative Preparation | 2.50 |
| | Example 1 (Ref.) | |

Referring to the results of Table 4, EOD including the semiconductor nanoparticles of the preparation examples, compared with EOD including the semiconductor nanoparticles of the comparative preparation example, exhibited significantly high current density. This result suggested that the semiconductor nanoparticle including metal dopants according to the embodiments exhibited an increase in electron transport characteristics, wherein the electron transport (ET) characteristics tended to further increase, as the metal dopants were more added.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An electroluminescent device, comprising
a first electrode and a second electrode spaced apart from each other, and a light emitting layer comprising a semiconductor nanoparticle and disposed between the first electrode and the second electrode,
wherein the semiconductor nanoparticle is configured to emit blue light,
a peak emission wavelength of the blue light is greater than or equal to about 440 nanometers and less than or equal to about 480 nanometers,
the semiconductor nanoparticle comprises zinc, tellurium, selenium, and sulfur,
the semiconductor nanoparticle further comprises a metal dopant,
the semiconductor nanoparticle does not comprise cadmium, and
the metal dopant comprises aluminum, gallium, zirconium, hafnium, magnesium, or a combination thereof.

2. The electroluminescent device of claim 1, wherein
in the semiconductor nanoparticle, a mole ratio of tellurium to selenium is less than about 0.1.

3. The electroluminescent device of claim 1, wherein
the metal dopant comprises aluminum, and in the semiconductor nanoparticle, a mole ratio of aluminum to sulfur is less than or equal to about 0.09.

4. The electroluminescent device of claim 1, wherein
the metal dopant comprises gallium, and in the semiconductor nanoparticle, a mole ratio of gallium to sulfur is greater than or equal to about 0.1.

5. The electroluminescent device of claim 1, wherein
the metal dopant comprises zirconium and in the semiconductor nanoparticle, a mole ratio of zirconium to sulfur is greater than or equal to about 0.05.

6. The electroluminescent device of claim 1, wherein
the peak emission wavelength of the blue light is greater than or equal to about 445 nanometers and less than or equal to about 475 nanometers.

7. The electroluminescent device of claim 1, wherein
the semiconductor nanoparticle comprises a first semiconductor nanocrystal; and a third semiconductor nanocrystal, the first semiconductor nanocrystal comprises zinc, selenium, and tellurium, and the third semiconductor nanocrystal comprises zinc and sulfur.

8. The electroluminescent device of claim 1, wherein
a mole ratio of the metal dopant to tellurium in the semiconductor nanoparticle is greater than or equal to about 0.001 and less than or equal to about 50.

9. The electroluminescent device of claim 1, wherein
the semiconductor nanoparticle does not comprise an indium phosphide, a copper indium sulfide, or a combination thereof.

10. The electroluminescent device of claim 1, wherein
the light emitting layer has an intensity ratio of the metal dopant to sulfur at a center of an average thickness of the light emitting layer in a depth profile of secondary ion mass spectrometry of greater than or equal to about 0.1 and less than or equal to about 10.

11. A method for manufacturing a semiconductor nanoparticle, which comprises:
disposing the light emitting layer comprising the semiconductor nanoparticle on the first electrode; and
disposing the second electrode on the light emitting layer,
wherein preparing of the semiconductor nanoparticle in the light emitting layer comprises
admixing a particle comprising zinc, selenium, and tellurium, a zinc precursor, and a sulfur precursor into a reaction medium; and the heating the reaction medium to a reaction temperature,
wherein in the method, the sulfur precursor comprises a product from a reaction between a metal dopant compound and an organic thiol compound,
the metal dopant compound comprises aluminum, magnesium, gallium, zirconium, hafnium, or a combination thereof,
the reaction of the metal dopant compound and the organic thiol compound is performed at a first temperature of less than 100° C., and
the reaction temperature is greater than or equal to about 245° C. and less than or equal to about 400° C.,
wherein the semiconductor nanoparticle is configured to emit blue light,
a peak emission wavelength of the blue light is greater than or equal to about 440 nanometers and less than or equal to about 480 nanometers,
the semiconductor nanoparticle comprises zinc, tellurium, selenium, and sulfur,
the semiconductor nanoparticle further comprises a metal dopant,
the semiconductor nanoparticle does not comprise cadmium, and
the metal dopant comprises aluminum, gallium, zirconium, hafnium, magnesium, or a combination thereof.

12. The method of claim 11, wherein
the reaction between the metal dopant compound and the organic thiol compound comprises contacting the metal dopant and the organic thiol compound in an organic solvent at the first temperature, wherein the first temperature is less than or equal to about 90° C., and
the contacting is accompanied by an exothermic reaction.

13. The method of claim 12, wherein
a metal thiolate is formed by a reaction between the metal dopant compound and the organic thiol compound.

14. The method of claim 11, wherein
the metal dopant compound comprises a trialkyl aluminum, a dialkyl magnesium, a zirconium alkoxide, a gallium alkoxide, a hafnium alkoxide, or a combination thereof.

15. The method of claim 11, wherein
the reaction temperature is greater than or equal to about 300° C. and less than or equal to about 380° C.

16. A display device comprising the electroluminescent device of claim 1.

17. The display device of claim 16, wherein
the display device is configured to be included in a virtual reality display device, an augmented reality display device, a portable terminal device, a monitor, a laptop, a television, an electronic board, a camera, or an electrical component.

18. The electroluminescent device of claim 1, wherein
the metal dopant comprises aluminum, and in the semiconductor nanoparticle, a mole ratio of aluminum to sulfur is greater than or equal to about 0.001 and less than or equal to about 0.4.

19. The electroluminescent device of claim 1, wherein
the metal dopant comprises gallium, and in the semiconductor nanoparticle, a mole ratio of gallium to sulfur is greater than or equal to about 0.01 and less than or equal to about 0.1.

20. The electroluminescent device of claim 1, wherein
the metal dopant comprises zirconium and in the semiconductor nanoparticle, a mole ratio of zirconium to sulfur is greater than or equal to about 0.01 and less than or equal to about 0.4.
